(19) United States
(12) Patent Application Publication
(10) Pub. No.: US 2004/0109342 A1
(43) Pub. Date: Jun. 10, 2004

(54) Semiconductor memory device producible with incorporated memory switched from RAM to ROM

(75) Inventor: Takeshi Fujino, Hyogo (JP)

Correspondence Address: McDermott, Will & Emery, 600 13th Street, N.W., Washington, DC, 20005-3096, US

(73) Assignee: MITSUBISHI DENKI KABUSHIKI KAISHA

(21) Appl. No.: 10/419,940

(22) Filed: Apr. 22, 2003

(30) Foreign Application Priority Data
Dec. 4, 2002 (JP) 2002-352787 (P)

(51) Int. Cl. G11C 11/24

(52) U.S. Cl. 365/149

(57) ABSTRACT

In a development stage, memory incorporated in a semiconductor memory device is entirely produced to be RAM, and in a mass-production stage, a region accommodating a program is altered into ROM by changing a mask after an interconnection process. In altering into the ROM, an electrode plate having been a storage node of a capacitor of a DRAM is connected for each memory cell array and coupled with a fixed potential. Whether to couple an access transistor with a fixed potential depends on whether provide an opening of an insulation film. A chip for development and that for mass-production can commonly be fabricated up to an intermediate step of the process and the chip for mass-production can rapidly be supplied.

### BACKGROUND OF THE INVENTION

1. Field of the Invention

The present invention relates generally to semiconductor devices and particularly to semiconductor devices including memory with dynamic random access memory (DRAM) at least having a portion fabricated differently to serve as read only memory (ROM).

2. Description of the Background Art

In initial development of a system program in connection for example with a microcomputer for incorporation or the like that is incorporated in an electrical product a microcomputer with flash memory embedded together is typically used. The microcomputer with flash memory embedded together allows the system program to be readily changed. With the computer mounted in the product, the program can be developed in the product, rewritten a number of times to confirm an operation.

In contrast, after the program has completely been developed and its contents have been fixed the product is mass-produced typically with a microcomputer having an ROM mounted thereon. The flash memory is replaced with the ROM in mass-production because a microcomputer having the ROM mounted thereon provides a smaller chip area and hence is more inexpensive than that having the flash memory mounted thereon.

This, however, requires that two types of chips be prepared for development and mass-production. Furthermore, it is also an issue to be addressed that it is becoming difficult for state-of-the-art fabrication processes to embed a flash memory.

In preparing the two types of chips, the master slice system may be applied to reduce the period for the development. The master slice system is a fabrication technique including a master step previously preparing a standard chip having a transistor arranged thereon and a slice step altering an electrical connection between transistors to provide a function required. Producing and stocking master slices having undergone the master step, having a well initially provided and a transistor finally fabricated and thus completed, allows them to be subjected to the slice step immediately when the function required is determined. The period for the development can thus be reduced.

More specifically, all of the memories mounted on a microcomputer chip are incorporated as random access memory (RAM). In development, the RAM is externally loaded with a program and operated. In mass-production, the slice step's slice mask is simply revised to alter a program region's RAM into a ROM having a program code stored therein. This allows an LSI in the development and that in the mass-production to be implemented with a single master slice and also advantageously provides for a desirably changeable ratio in capacitance between the RAM and ROM regions.

Such an object can also be achieved by altering static random access memory (SRAM) into ROM, as studied in Japanese Patent Laying-Open No. 5-314776. An SRAM, however, has an area approximately no less than five times that a ROM. As such, employing the SRAM results in an increased chip area in the mass-production and hence an increased cost.

Japanese Patent Laying-Open Nos. 5-314776 and 5-189988 disclose that a DRAM smaller in area than a SRAM is altered into a ROM. As disclosed in Japanese Patent Laying-Open No. 5-189988, however, when a DRAM cell is altered into a ROM, a memory cell's access transistor has a storage node connected to a fixed potential, which has either the high level or the low level, and to store data opposite to the fixed potential, the storage node is not connected to the fixed potential. Rather, upon start-up, the data opposite to the fixed potential is written to the DRAM cell to store it. In this technique, data opposite to the fixed data is required to be written to capacitors of an entire ROM area in start-up. Further, since in operation a refresh operation is required, the memory does not serve as a completely non-volatile memory.

Furthermore, this technique requires the step of fixing in potential a cell plate corresponding a polarity opposite a storage node of a capacitor included in a memory cell of DRAM, and selectively etching the capacitor's insulation film. This entails an additional step, and it is also difficult to selectively etch the capacitor's insulation film alone since the film has a significantly small thickness. For example, together with an underlying capacitor electrode and an interlayer insulating film, an insulation film would be readily provided with a hole. However, adding an insulation film only to a specific memory cell while not providing a different memory cell with an insulation film may result in a damage to the exact insulation film when resist is removed.

Furthermore, Japanese Patent Laying-Open No. 5-314776 discloses a DRAM cell layout requiring that a memory cell have a storage node connectable to both of two types of fixed potentials, ground potential and power supply potential. Selectively supplying such two types of fixed potentials to the storage node entails arranging two types of power supply lines with a pitch comparable to a word line, which may contribute to reduced yields.

### SUMMARY OF THE INVENTION

The present invention contemplates a semiconductor memory device using a DRAM cell capable of providing a memory area equivalent to or smaller than a typical ROM as an RAM, capable of altering the DRAM cell into ROM without a substantially changed, reading, peripheral circuit layout by revising a slice mask (a mask mainly for an interconnection step provided after a transistor is fabricated).

The present invention generally provides a semiconductor device comprised of a first memory cell array arranged in a first region to store information in a volatile manner. The first memory cell array includes a first electrode plate receiving a first fixed potential, a plurality of second electrode plates arranged opposite to the first electrode plate with an insulation film posed therebetween, a plurality of first bit lines, a plurality of first word lines and a plurality of first access transistors each having one end connected to a respective one of the plurality of second electrode plates. The plurality of first access transistors each have the other end connected to a corresponding one of the plurality of first bit lines, and a control electrode connected to a corresponding one of the plurality of first word lines. The semiconductor device is also comprised of a second memory cell array arranged in a second region to store information in a non-volatile manner. The second memory cell array includes a third electrode plate receiving a second fixed potential. The third electrode plate and the plurality of second electrode plates are fabricated in a single process. The second memory cell array further includes a plurality of second bit lines, a plurality of second word lines and a plurality of second access transistors. The plurality of second transistors each have a control electrode connected to a corresponding one of the plurality of second word lines, one end connected to a corresponding one of the plurality of second bit lines. The other end of each of the plurality of second access transistors is determined, according to storage information of the second memory cell array, whether or not to be connected to the third electrode plate.

Thus a main advantage of the present invention is that a chip for development and a chip for mass-production can commonly be fabricated up to an intermediate step of the process and the chip for mass-production can rapidly be supplied. The present invention can thus provide a semiconductor device allowing inexpensive transition from a program development stage to a mass-production stage.

The foregoing and other objects, features, aspects and advantages of the present invention will become more apparent from the following detailed description of the present invention when taken in conjunction with the accompanying drawings.

### BRIEF DESCRIPTION OF THE DRAWINGS

In the drawings:

FIG. 1 is a schematic block diagram showing a configuration of a semiconductor memory device 1 of the present invention in a first embodiment;

FIG. 2 is a circuit diagram for illustrating a sense amplifier band a memory cell array in FIG. 1;

FIG. 3 is a circuit diagram showing a configuration of a sense amplifier band 32 shown in FIG. 2;

FIGS. 4A-4C illustrate a relationship between an arrangement, structure and the like of a memory cell arranged in a RAM cell array of FIG. 2 and a circuit diagram;

FIGS. 5A-5C illustrate a relationship between an arrangement, structure and the like of a memory cell arranged in a ROM cell array of FIG. 2 and a circuit diagram;

FIGS. 6A-13B illustrate a process for fabricating a DRAM cell of memory cell array 22 of FIG. 2;

FIGS. 14A-21B illustrate a process for fabricating a ROM cell of memory cell array 24 of FIG. 2;

FIGS. 22A and 22B illustrate a storage operation of a RAM portion;

FIGS. 23A and 23B illustrate storing and reading data to and from a ROM portion;

FIGS. 24A-24C illustrate a read operation of a RAM portion;

FIGS. 25A-25C illustrate a read operation of a ROM portion;

FIG. 26 is a circuit diagram showing a RAM portion of a main portion 680 of a semiconductor memory device in a second embodiment;

FIG. 27 is a circuit diagram showing a ROM portion of main portion 680 of the semiconductor memory device in the second embodiment;

FIGS. 28A-28C illustrate an operation of the RAM portion in the second embodiment;

FIGS. 29A-29C illustrate a read operation of the ROM portion in the second embodiment;

FIGS. 30A and 30B are diagrams for illustrating a program developing microcomputer after a program has been developed and fixed;

FIGS. 31A and 31B are diagrams for illustrating a development employing a microcomputer incorporating the semiconductor memory device of the present invention; and

FIG. 32 shows an extemporary configuration accommodating in a package the microcomputer for development described in FIG. 31A.

### DESCRIPTION OF THE PREFERRED EMBODIMENTS

Hereinafter the present invention in embodiments will more specifically be described with reference to the drawings. In the figures, like reference characters denote like components.

First Embodiment

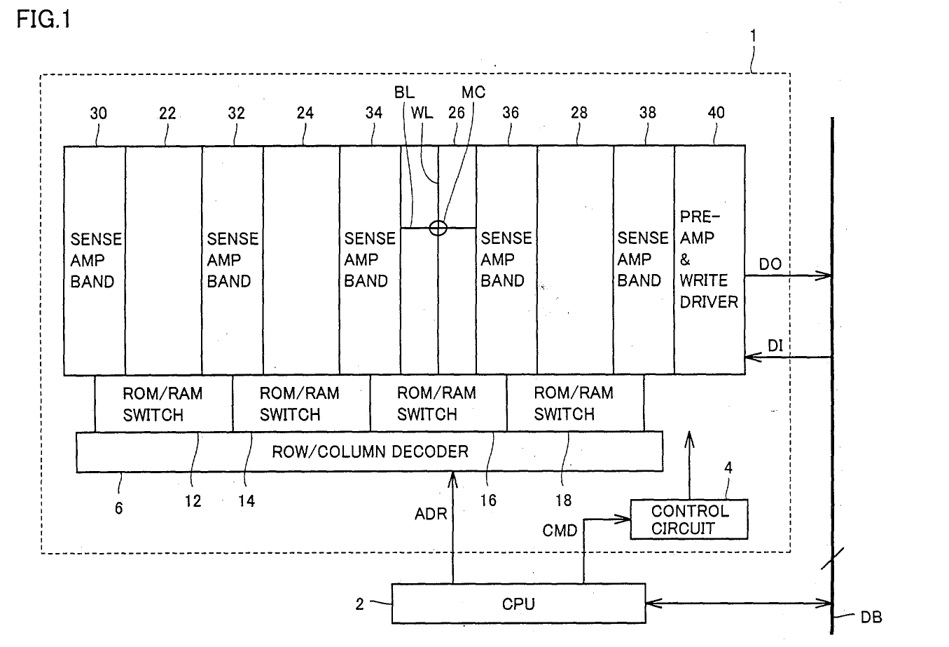

FIG. 1 is a schematic block diagram showing a configuration of a semiconductor memory device 1 of the present invention in a first embodiment.

With reference to FIG. 1, semiconductor memory device 1 includes a row/column decoder 6 receiving an address signal ADR from a central processing unit (CPU) 2, a control circuit 4 receiving a command signal CMD from CPU2, memory cell arrays 22-28, sense amplifier bands 30-38, a preamplifier and write driver 40, and switches 12-18.

Memory cell arrays 22-28 each include memory cells MCs arranged in rows and columns, a bit line BL provided to correspond to a column of memory cells MCs, and a word line WL provided to correspond to a row of memory cells MCs. FIG. 1 shows a single memory cell MC, a single bit line BL and a single word line WL of memory cell array 26 representatively.

Row/column decoder 6 receives address signal ADR from CPU2 and selects word line WL of memory cell array 26. Simultaneously it outputs a select signal to a sense amplifier band to select a bit line.

Control circuit 4 operates in response to command signal CMD received from CPU2 to provide instructions of read, write and other operations for the entirety of a chip. The sense amplifier band amplifies data of memory cell MC read on a bit line and outputs the amplified data to a preamplifier. The preamplifier outputs a data output signal DO on a data bus DB. The write driver receives a data input signal DI through data bus DB, amplifies the signal and outputs it to the sense amplifier band. Through a bit line selected in the sense amplifier band the data input signal is transmitted to a memory cell.

Switches 12-18 designate switching between a ROM and a RAM after the master slice step for each memory cell array. Switches 12-18 are provided for memory cell arrays 22-28, respectively.

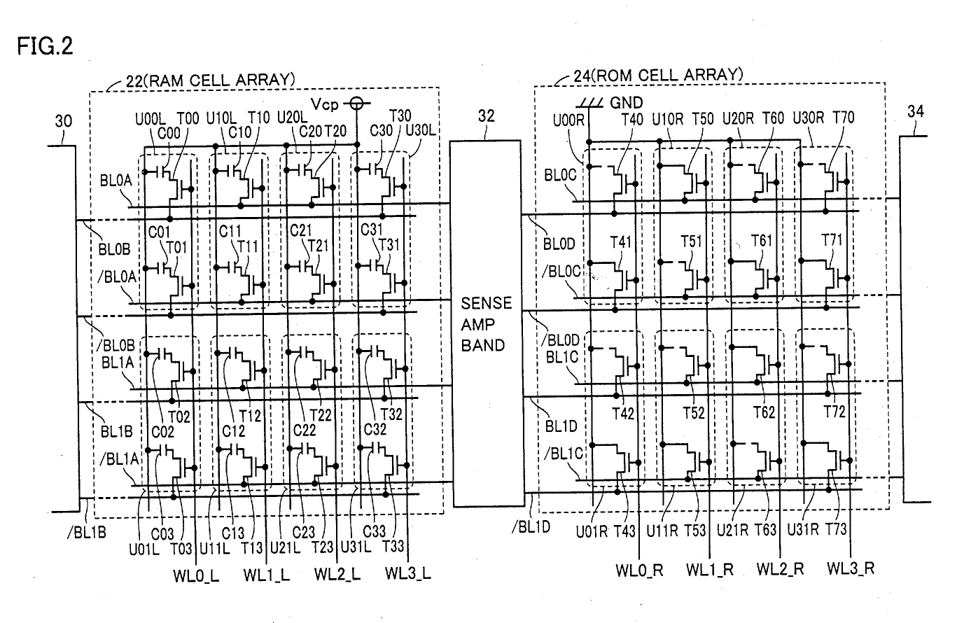

FIG. 2 is a circuit diagram for illustrating a sense amplifier band and a memory cell array of FIG. 1.

With reference to FIG. 2, memory cell arrays 22 and 24 share sense amplifier band 32. As switch 12 of FIG. 1 selects a RAM operation, memory cell array 22 operates as a RAM cell array. A memory cell array thus providing the RAM operation will in the present specification be referred to as a “RAM portion.” In contrast, memory cell array 24 operates as a ROM cell array as switch 14 of FIG. 1 selects a ROM operation. A memory cell array thus providing the ROM operation will also in this specification be referred to as a “ROM portion.”

Memory cell array 22 includes memory cell units U00L-U31L. Memory cell unit U00L-U3 1L is a so-called twin memory cell, each including two transistors and two capacitors.

Memory cell unit U00L includes a capacitor C00 having one end coupled with a cell plate potential VCP, an n channel MOS transistor T00 connected between the other end of capacitor C00 and a bit line BL0B, a capacitor C01 having one end coupled with cell plate potential VCP, and an n channel MOS transistor T01 connected between the other end of capacitor C01 and a bit line /BL0B. N channel MOS transistors T00, T01 have their respective gates both connected to a word line WL0_L.

Memory cell unit U01L includes a capacitor C02 having one end coupled with cell plate potential VCP, an n channel MOS transistor T02 connected between the other end of capacitor C02 and a bit line BL1B, a capacitor C03 having one end coupled with cell plate potential VCP, and an n channel MOS transistor T03 connected between the other end of capacitor C03 and a bit line /BL1B. N channel MOS transistors T02, T03 have their respective gates both connected to word line WL0_L.

Memory cell unit U10L includes a capacitor C10 having one end coupled with cell plate potential VCP, an n channel MOS transistor T10 connected between the other end of capacitor C10 and a bit line BL0A, a capacitor C11 having one end coupled with cell plate potential VCP, and an n channel MOS transistor T11 connected between the other end of capacitor C11 and a bit line /BL0A. N channel MOS transistors T10, T11 have their respective gates both connected to a word line WL1_L.

Memory cell unit U11L includes a capacitor C12 having one end coupled with cell plate potential VCP, an n channel MOS transistor T12 connected between the other end of capacitor C12 and a bit line BL1A, a capacitor C13 having one end coupled with cell plate potential VCP, and an n channel MOS transistor T13 connected between the other end of capacitor C13 and a bit line /BL1A. N channel MOS transistors T12, T13 have their respective gates both connected to word line WL1_L.

Memory cell unit U20L includes a capacitor C20 having one end coupled with cell plate potential VCP, an n channel MOS transistor T20 connected between the other end of capacitor C20 and bit line BL0A, a capacitor C21 having one end coupled with cell plate potential VCP, and an n channel MOS transistor T21 connected between the other end of capacitor C21 and bit line /BL0A. N channel MOS transistors T20, T21 have their respective gates both connected to a word line WL2_L.

Memory cell unit U21L includes a capacitor C22 having one end coupled with cell plate potential VCP, an n channel MOS transistor T22 connected between the other end of capacitor C22 and bit line BL1A, a capacitor C23 having one end coupled with cell plate potential VCP, and an n channel MOS transistor T23 connected between the other end of capacitor C23 and bit line /BL1A. N channel MOS transistors T22, T23 have their respective gates both connected to a word line WL2_L.

Memory cell unit U30L includes a capacitor C30 having one end coupled with cell plate potential VCP, an n channel MOS transistor T30 connected between the other end of capacitor C30 and a bit line BL1B, a capacitor C31 having one end coupled with cell plate potential VCP, and an n channel MOS transistor T31 connected between the other end of capacitor C31 and a bit line /BL1B. N channel MOS transistors T30, T31 have their respective gates both connected to a word line WL3_L.

Memory cell unit U31L includes a capacitor C32 having one end coupled with cell plate potential VCP, an n channel MOS transistor T32 connected between the other end of capacitor C32 and bit line BL1B, a capacitor C33 having one end coupled with cell plate potential VCP, and an n channel MOS transistor T33 connected between the other end of capacitor C33 and bit line /BL1B. N channel MOS transistors T32, T33 have their respective gates both connected to word line WL3_L.

Bit lines BL0A, /BL0A, BL1A, /BL1A are connected to sense amplifier band 32. Bit lines BL0B, /BL0B, BL1B, /BL1B are connected to sense amplifier band 30.

In memory cell array 24, the portions corresponding to the storage nodes of the capacitors of RAM portion are connected to provide a single plate, as will be described hereinafter. This plate receives a ground potential. In the present specification this plate will be referred to as a “fixed-potential plate.”

Memory array 24 includes memory cell units U00R-U31R each storing one bit of data in non-volatile manner.

Memory cell unit U00R includes an n channel MOS transistor T40 having one end connected to a bit line BLOD and the other end isolated from the fixed-potential plate to float, and its gate connected to a word line WL0_R, and an n channel MOS transistor T41 connected between a bit line /BLOD and the fixed-potential plate and having its gate connected to word line WLO_R.

Memory cell unit U01R includes an n channel MOS transistor T42 having one end connected to a bit line BL1D and the other end isolated from the fixed-potential plate to float, and its gate connected to word line WL0_R, and an n channel MOS transistor T43 connected between bit line /BL0D and the fixed-potential plate and having its gate connected to word line WL0_R.

Memory cell unit U10R includes an n channel MOS transistor T50 connected between a bit line /BL0C and the fixed-potential plate and having its gate connected to a word line WL1_R, and an n channel MOS transistor T51 having one end connected to a bit line /BL0C and the other end isolated from the fixed-potential plate to float, and its gate connected to. a word line WL1_R.

Memory cell unit U1 R includes an n channel MOS transistor T52 having one end connected to a bit line BL1C and the other end isolated from the fixed-potential plate to float, and its gate connected to a word line WL1_R, and an n channel MOS transistor T53 connected between a bit line BL1C and the fixed-potential plate and having its gate connected to word line WL1_R.

Memory cell unit U20R includes an n channel MOS transistor T60 having one end connected to a bit line BL0C and the other end isolated from the fixed-potential plate to float, and its gate connected to a word line WL2_R, and an n channel MOS transistor T61 connected between a bit line /BLOC and the fixed-potential plate and having its gate connected to word line WL2_R.

Memory cell unit U2 IR includes an n channel MOS transistor T62 connected between bit line BLIC and the fixed-potential plate and having its gate connected to word line WL2_R, and an n channel MOS transistor T63 having one end connected to bit line /BL1C and the other end isolated from the-fixed-potential plate to float, and its gate connected to word line WL2_R.

Memory cell unit U30R includes an n channel MOS transistor T70 having one end connected to a bit line BL0D and the other end isolated from the fixed-potential plate to float, and its gate connected to a word line WL3_R, and an n channel MOS transistor T71 connected between bit line /BLOD and the fixed-potential plate and having its gate connected to word line WL3_R.

Memory cell unit U3 1R includes an n channel MOS transistor T72 having one end connected to bit line BL1D and the other end isolated from the fixed-potential plate to float, and its gate connected to word line WL3_R, and an n channel MOS transistor T73 connected between bit line /BL0D and the fixed-potential plate and having its gate connected to word line WL3_R.

Bit lines BL0C, /BL0C, BL1C, /BL1C are connected to sense amplifier band 34. Bit lines BL0D, /BL0D, BL1D, /BL1D are connected to sense amplifier band 32.

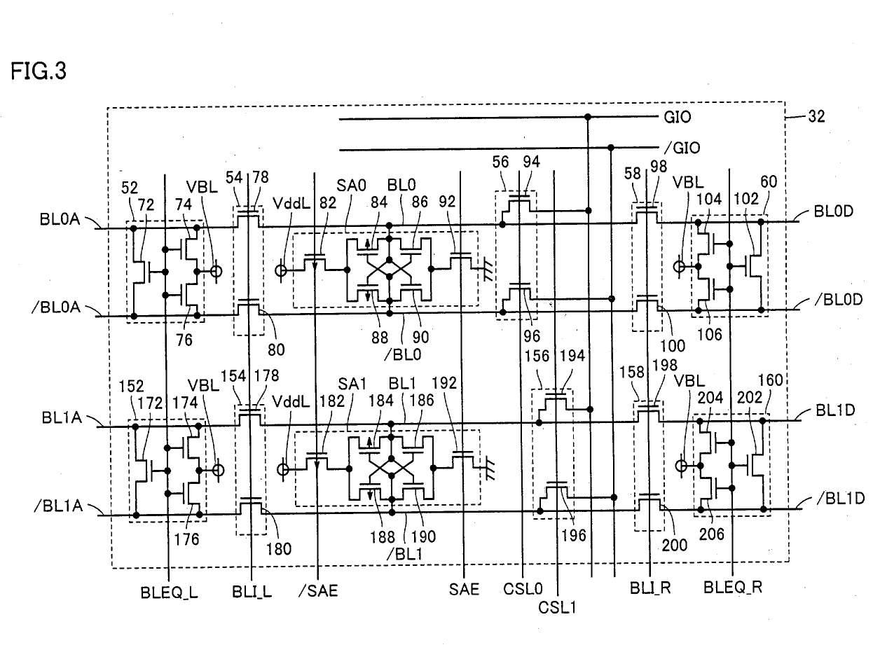

FIG. 3 is a circuit diagram showing a configuration of sense amplifier band 32 of FIG. 2.

With reference to FIG. 3, sense amplifier band 32 includes an equalize circuit 52 for setting bit lines BL0A and /BL0A to have an equalize potential VBL, a connection circuit 54 operative in response to a signal BLI_L to connect bit lines BL0A, /BL0A to bit lines BL0, /BL0, respectively, and a sense amplifier SA0 operative in response to an enable signal SAE, /SAE to amplify a difference in potential introduced between bit lines BL0 and /BL0.

Sense amplifier band 32 also includes a select gate 56 operative in response to a column select line CSLO being enabled to connect bit lines BL0, /BL0 to global IO lines GIO, /GIO, respectively, a connection circuit 58 operative in response to a signal BLI_R to connect bit lines BL0D, /BL0D to bit lines BL0, /BL0, respectively, and an equalize circuit 60 operative in response to an equalize signal BLEQ_R to equalize bit lines BL0D, /BL0D to have equalize potential VBL.

Sense amplifier band 32 further includes an equalize circuit 152 for setting bit lines BL1A and /BL1A to have equalize potential VBL, a connection circuit 154 operative in response to signal BLI_L to connect bit lines BL1A, /BL1A to bit lines BL1, /BL1, respectively, and a sense amplifier SA1 operative in response to enable signal SAE, /SAE to amplify a difference in potential introduced between bit lines BL1 and /BL1.

Sense amplifier band 32 also includes a select gate 156 operative in response to a column select line CSLO being enabled to connect bit lines BL1, /BL1 to global IO lines GIO, /GIO, respectively, a connection circuit 158 operative in response to signal BLI_R to connect bit lines BL1D, /BL1D to bit lines BL1, /BL1, respectively, and an equalize circuit 160 operative in response to equalize signal BLEQ_R to equalize bit lines BL1D, /BL1D to have equalize potential VBL.

Equalize circuit 52 includes an n channel MOS transistor 72 connected between bit lines BL0A and /BL0A and having its gate receiving a signal BLEQ_L, an n channel MOS transistor 74 having one end coupled with equalize potential VBL and the other end to bit line BL0A, and its gate receiving signal BLEQ_L, and an n channel MOS transistor 76 having one end coupled with equalize potential VBL and the other end connected to bit line BL0A, and its gate receiving signal BLEQ_L.

Connection circuit 54 includes an n channel MOS transistor 78 connected between bit lines BL0A and BL0 and having its gate receiving signal BLI_L, and an n channel MOS transistor 80 connected between bit lines /BL0A and /BL0 and having its gate receiving signal BLI_L.

Sense amplifier SAO includes a p channel MOS transistor 82 having its source coupled with a power supply potential VddL and its gate receiving enable signal /SAE, a p channel MOS transistor 84 connected between the drain of p channel MOS transistor 82 and bit line BL0 and having its gate connected to bit line /BL0, and a p channel MOS transistor 88 connected between the drain of p channel MOS transistor 82 and bit line /BL0 and having its gate connected to bit line BL0.

Sense amplifier SA0 also includes an n channel MOS transistor 92 having its source coupled with a ground potential and its gate receiving enable signal SAE, an n channel MOS transistor 86 connected between bit line BL0 and the drain of n channel MOS transistor 92 and having its gate connected to bit line /BL0, and an n channel MOS transistor 90 connected between bit line /BL0 and the drain of n channel MOS transistor 92 and having its gate connected to bit line BL0.

Select gate 56 includes an n channel MOS transistor 94 connected between bit line BL0 and global IO line GIO and having its gate connected to column select line CSL0, and an n channel MOS transistor 96 connected between bit line /BL0 and global IO line /GIO and having its gate connected to column select line CLS0.

Connection circuit 58 includes an n channel MOS transistor 98 connected between bit lines BL0 and BL0D and having its gate receiving signal BLI_R, and an n channel MOS transistor 100 connected between bit lines /BL0 and /BL0D and having its gate receiving signal BLI_R.

Equalize circuit 60 includes an n channel MOS transistor 102 connected between bit lines BL0D and /BL0D and having its gate receiving a signal BLEQ_R, an n channel MOS transistor 104 having one end coupled with equalize potential VBL and the other end to bit line BL0D, and its gate receiving signal BLEQ_R, and an n channel MOS transistor 106 having one end coupled with equalize potential VBL and the other end connected to bit line /BL0D, and its gate receiving signal BLEQ_R.

Equalize circuit 152 includes an n channel MOS transistor 172 connected between bit lines BL1A and /BL1A and having its gate receiving a signal BLEQ_L, an n channel MOS transistor 174 having one end coupled with equalize potential VBL and the other end to bit line BL1A, and its gate receiving signal BLEQ_L, and an n channel MOS transistor 176 having one end coupled with equalize potential VBL and the other end connected to bit line BL1A, and its gate receiving signal BLEQ_L.

Connection circuit 154 includes an n channel MOS transistor 178 connected between bit lines BL1A and BL1 and having its gate receiving signal BLI_L, and an n channel MOS transistor 180 connected between bit lines /BL1A and /BL1 and having its gate receiving signal BLI_L.

Sense amplifier SAl also includes an n channel MOS transistor 182 having its source coupled with power supply potential VddL and its gate receiving enable signal /SAE, an n channel MOS transistor 184 connected between the drain of n channel MOS transistor 182 and bit line BL1 and having its gate connected to bit line /BL1, and an n channel MOS transistor 188 connected between the drain of n channel MOS transistor 182 and bit line /BL1 and having its gate connected to bit line BL1.

Sense amplifier SAl also includes an n channel MOS transistor 192 having its source coupled with a ground potential and its gate receiving enable signal SAE, an n channel MOS transistor 186 connected between bit line BLI and the drain of n channel MOS transistor 192 and having its gate connected to bit line /BL1, and an n channel MOS transistor 190 connected between bit line /BL1 and the drain of n channel MOS transistor 192 and having its gate connected to bit line BLI.

Select gate 156 includes an n channel MOS transistor 194 connected between bit line BL1 and global IO line GIO and having its gate connected to column select line CSL1, and an n channel MOS transistor 196 connected between bit line /BL1 and global IO line /GIO and having its gate connected to column select line CLS1.

Connection circuit 158 includes an n channel MOS transistor 198 connected between bit lines BLI and BLiD and having its gate receiving signal BLI_R, and an n channel MOS transistor 200 connected between bit lines /BL1 and /BL1D and having its gate receiving signal BLI_R.

Equalize circuit 160 includes an n channel MOS transistor 202 connected between bit lines BL1D and /BL1D and having its gate receiving a signal BLEQ_R, an n channel MOS transistor 204 having one end coupled with equalize potential VBL and the other end to bit line BL1D, and its gate receiving signal BLEQ_R, and an n channel MOS transistor 206 having one end coupled with equalize potential VBL and the other end connected to bit line /BL1D, and its gate receiving signal BLEQ_R.

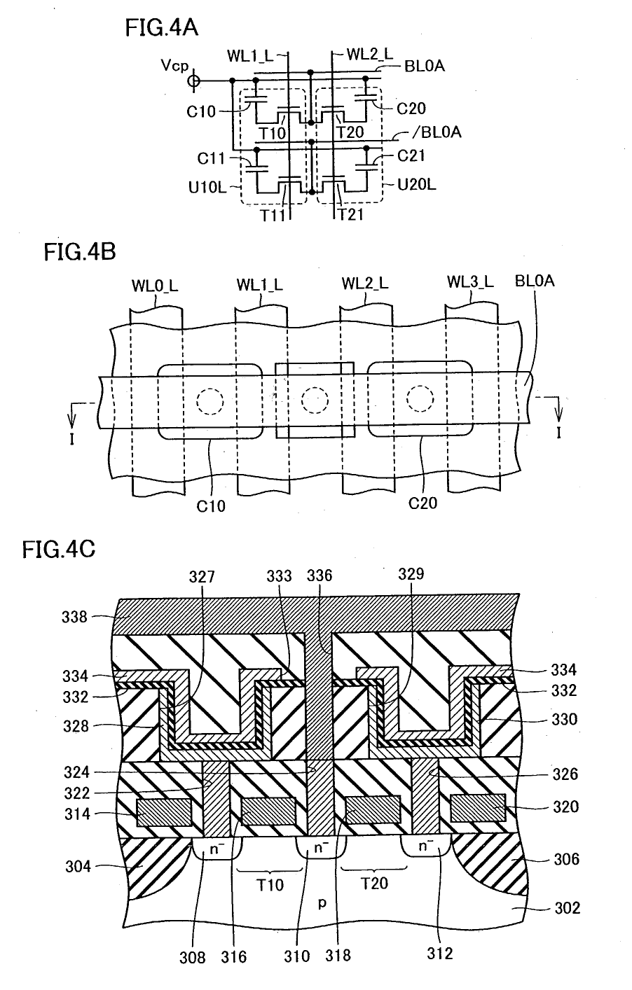

FIGS. 4A-4C are diagrams for illustrating a relationship between an arrangement, structure and the like of a memory cell arranged in a RAM cell array and a circuit diagram.

Reference will first be made to FIGS. 4A and 4B to describe a stacked DRAM cell where a memory cell array is used as RAM. FIG. 4A shows a circuit of memory cell units U10L, U20L of FIG. 2, extracted as corresponding to arrangement. It is connected, as has been described with reference to FIG. 2.

FIG. 4B is a plan view showing transistors T10, T20 and capacitors C10, C20 connected to bit line BL0A. Capacitor C10 has a center positioned between word lines WL0_L and WL1_L. Capacitor C20 has a center positioned between word lines WL2_L and WL3_L. Bit line BL0A overlies capacitors C10, C20 orthogonal to a word line and is connected between word lines WL1_L and WL2_L via a contact hole to a transistor's source/drain.

FIG. 4C is a cross section of FIG. 4B, taken along a line I-I.

With reference to FIGS. 4B and 4C, a p substrate 302 has a main surface provided with a device isolation regions 304, 306 and n doped regions 308, 310, 312 between device isolation regions 304 and 306. An interconnection 314 corresponding to word line WL0_L overlies device isolation region 304. An interconnection 316 corresponding to word line WL1_L overlies a region between n doped regions 308 and 310. An interconnection 318 corresponding to word line WL2_L overlies a region between n doped regions 310 and 312. An interconnection 320 corresponding to word line WL3_L overlies device isolation region 306. Note that interconnections 314-320 are formed for example of polycrystalline silicon.

On n doped regions 308, 310, 312 an insulation film is provided with contact holes 322, 324, 326 and therein a conductive plug is provided. Conductive films 328, 330 overlie contact holes 322, 326, respectively. Conductive films 328, 330 serve as an electrode of capacitor C10, C20 closer to a storage node. A thin insulation film 332 overlies conductive films 328, 330. A conductive film 334 serving as a cell plate electrode overlies insulation film 332.

On contact hole 324 a contact hole 336 is provided and therein a conductive plug is provided and thereon a conductive film 338 corresponding to bit line BL0A is provided.

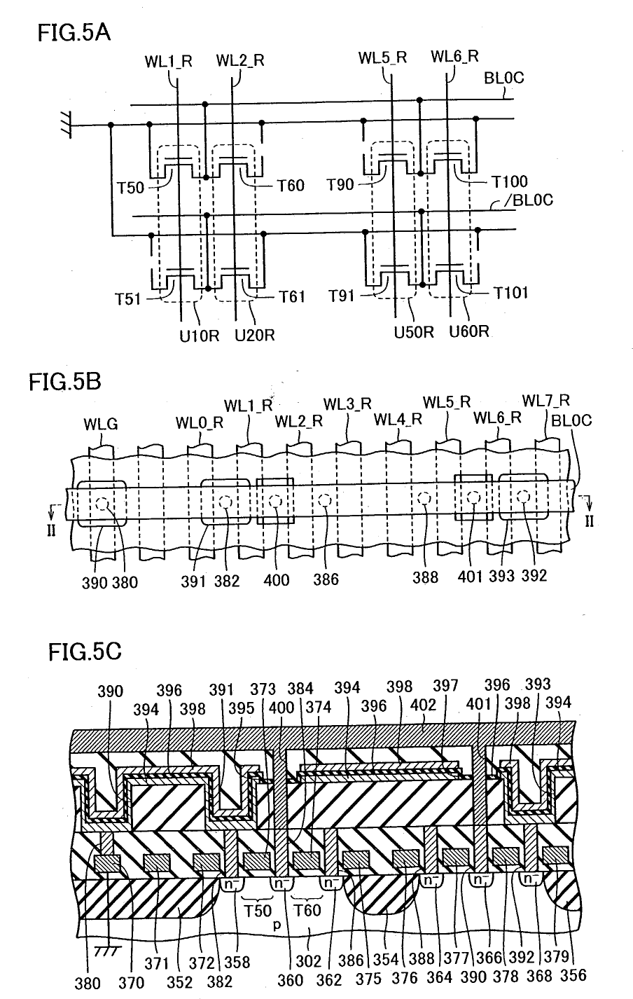

FIGS. 5A-5C are diagrams for illustrating a relationship between an arrangement, structure and the like of a memory cell arranged in the ROM cell array of FIG. 2 and a circuit diagram.

FIG. 5A is a circuit diagram illustrating the FIG. 2 memory cell units U1OR, U20R, U50R, U60R, as corresponding to a memory cell arrangement. Their components are connected, as has been described with. reference to FIG. 2.

FIG. 5B is a plan view for illustrating an arrangement corresponding to transistors T50, T60, T90, T100 of FIG. 5A connected to bit line BL0C. Bit line BL0C is arranged orthogonal to word lines WLG, WLO_R-WL7_R.

FIG. 5C is a cross section of FIG. 5B, taken along a line II-II.

With reference to FIGS. 5B and 5C, p type substrate 302 has an upper portion provided with device isolation regions 352, 354, 356, and n doped regions 358, 360, 362 between device isolation regions 352 and 354. N doped regions 364, 366, 368 are provided between device isolation regions 354 and 356. Interconnections 370-372 overlie device isolation region 352. An interconnection 373 overlies a region between n doped regions 358 and 360. Similarly an interconnection 374 overlies a region between n doped regions 360 and 362.

Interconnections 375, 376 overlie device isolation region 354. An interconnection 377 overlies a region between n doped regions 364 and 366. An interconnection 378 overlies a region between n doped regions 366 and 368. An interconnection 379 overlies device isolation region 356.

For example, interconnections 370-379 are formed of polycrystalline silicon. Interconnection 370 corresponds to word line WLG of FIG. 5B and interconnections 372-379 correspond to word lines WL0_R-WL7_R, respectively. To connect to interconnection 370 a contact hole 380 is provided and therein a conductive plug is provided.

On n doped region 358 a contact hole 382 is provided and in the contact hole a conductive plug is provided. On n doped region 360 a contact hole 384 is provided and therein a conductive plug is provided. On n doped region 362 a contact hole is provided and therein a conductive plug is provided.

On n doped regions 364, 366, 368 contact holes 388, 390, 392 are provided, respectively, and in each contact hole a conductive plug is provided.

Hereinafter will be described a portion that significantly varies when a RAM cell array alters into a ROM cell array. For DRAM, contact holes 380, 382, 392 underlie openings 390, 391, 393, respectively, corresponding to an opening for forming a capacitor. In FIG. 5A each transistor has one end coupled with a bit line. Whether the other end is coupled with a ground potential is determined by whether this opening is provided.

In openings 390, 391, 393 a conductive film 394 is provided. Conductive film 394 receives a ground potential via interconnection 370 and the conductive plug in contact hole 380. Contact hole 382 overlying doped region 358, and opening 344 allow doped region 358 to be connected to conductive film 394 and thus coupled with the ground potential.

On doped region 362 a contact hole 386 is provided, although an insulation film overlying the contact hole is not provided with an opening corresponding to opening 344. As such, doped region 362 is isolated from conductive film 394 and, as shown in FIG. 5A, when transistor T60 has one end connected to a bit line, it has the other end disconnected from the ground potential.

On conductive film 394 a thin insulation film 396 corresponding to an insulation film between electrodes of a capacitor of a DRAM cell array is provided and thereon a conductive film 398 corresponding to a cell plate of the DRAM cell array is provided. Conductive film 398 is isolated from a cell plate potential. It is floating or coupled with a ground voltage equal to conductive film 394 serving as the fixed-potential plate.

On contact holes 384, 390 contact holes 400, 401 for connecting a bit line are provided, respectively, and therein a conductive plug is provided. An interconnection 402 corresponding to bit line BL0C is provided on the insulation film provided with contact holes 400, 401.

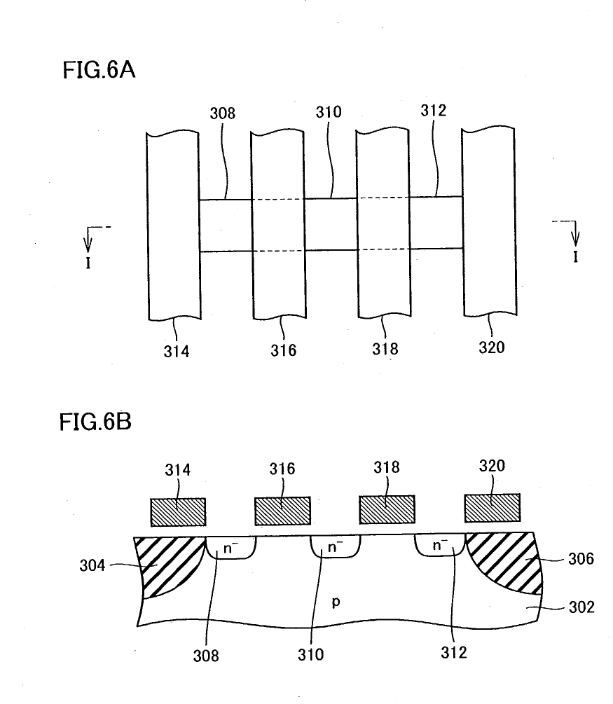

FIGS. 6A-13B illustrate a process for fabricating a DRAM cell of memory cell array 22 shown in FIG. 2.

With reference to FIGS. 6A and 6B, on an active region, interconnections 316, 338 serving as a word line are arranged, and at an intersection, a memory cell transistor is fabricated. More specifically, in p substrate 302 at a portion other than the active region device isolation regions 304, 306 are provided and interconnections 314, 316, 318, 320 are provided thereon, and by introducing n dopant n doped regions 308, 310,312 are provided. In other words, a transistor having a gate electrode corresponding to interconnection 316 and a transistor having a gate electrode corresponding to interconnection 318 are provided.

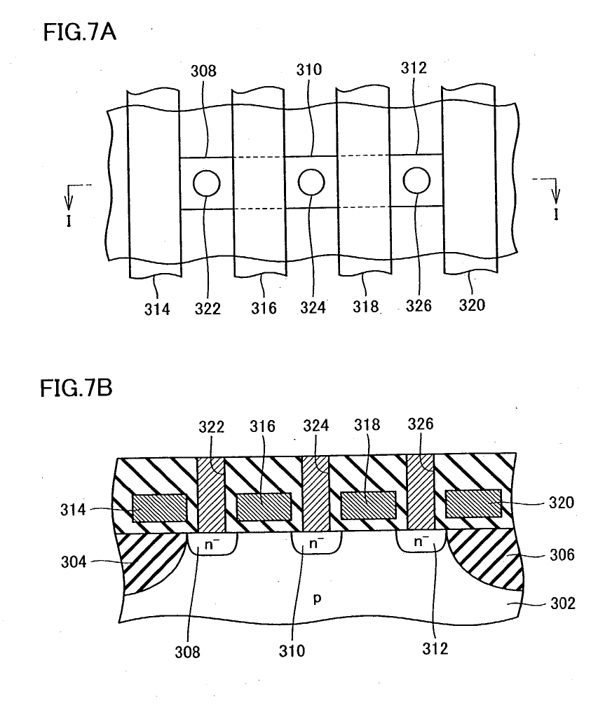

With reference to FIGS. 7A and 7B, after an insulation film is provided on a gate interconnection a memory cell transistor's source/drain contacts 322, 324, 326 are provided.

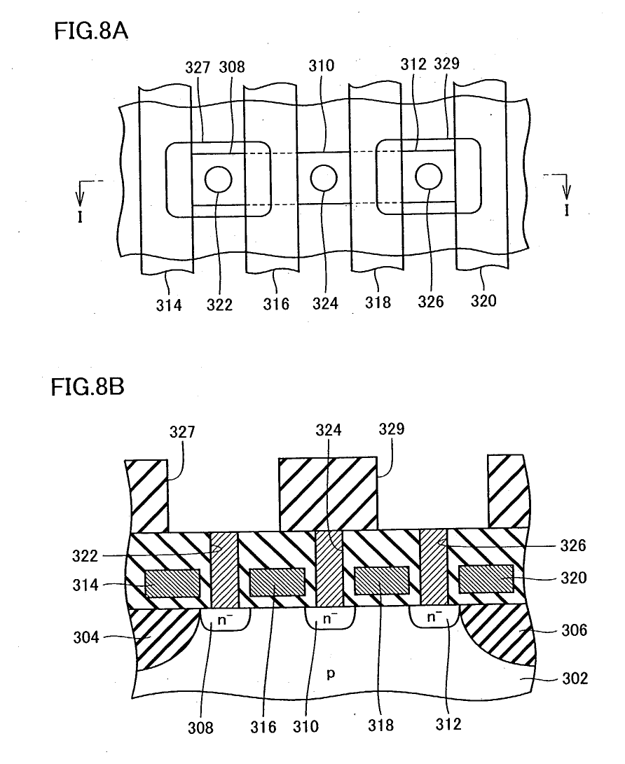

With reference to FIGS. 8A and 8B, after an insulation film is again provided, openings 327, 329 are provided for forming a capacitor storing an electric charge corresponding to stored information in DRAM.

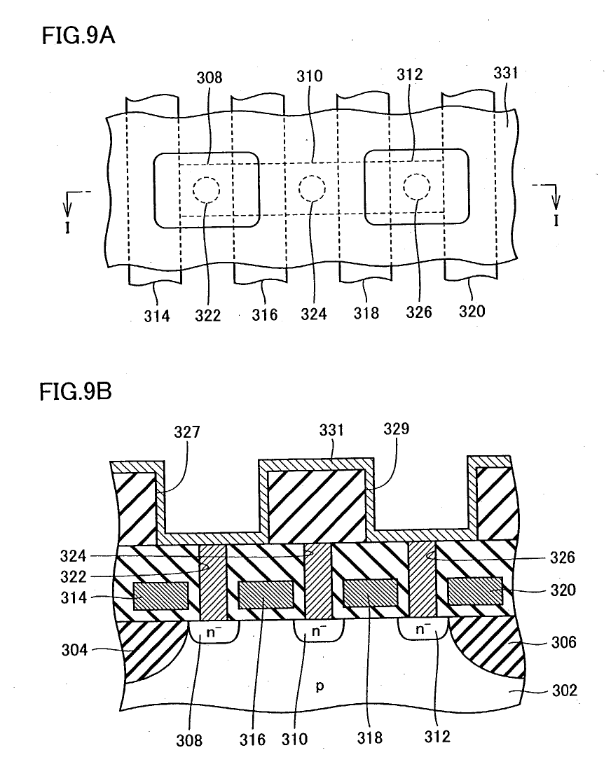

With reference to FIGS. 9A and 9B, a conductive film 331 serving as a storage node of a capacitor of a DRAM cell is provided on the insulation film and an internal wall of opening 327, 329.

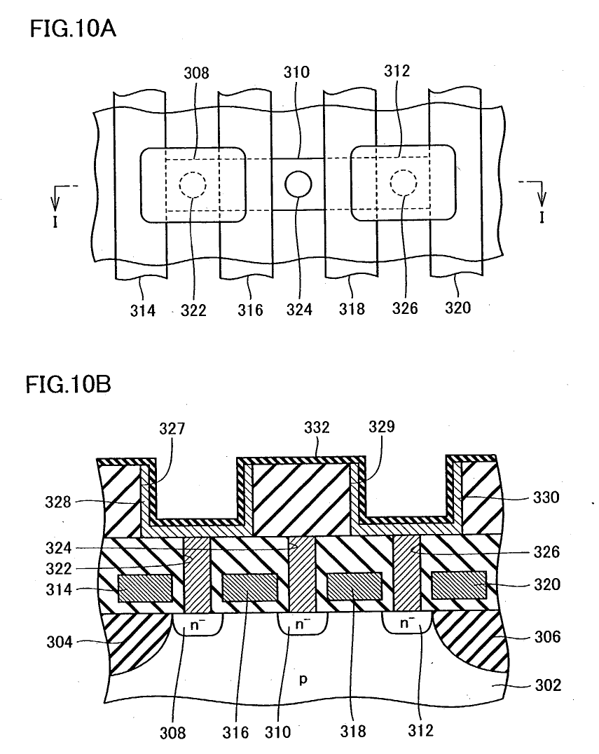

With reference to FIG. 10A and 10B, after resist is applied on the entire surface a photomask is used to expose a portion other than the opening to remove the resist of the exposed portion. The intermediate product is then etched back and only in openings 327, 329 conductive films 328, 330 remain. A film 322 serving as an insulation film between capacitor electrodes is then deposited.

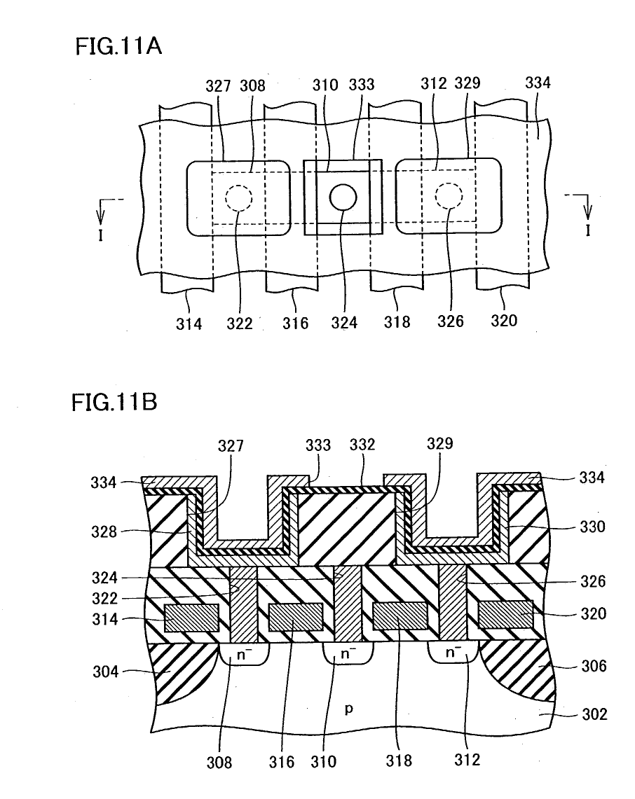

With reference to FIGS. 11A and 11B, a conductive film 334 serving as a memory cell capacitor's opposite electrode, i.e., a cell plate is provided on an entire surface. Subsequently, only inside a region 333 conductive film 334 is removed to form a bit line contact hole.

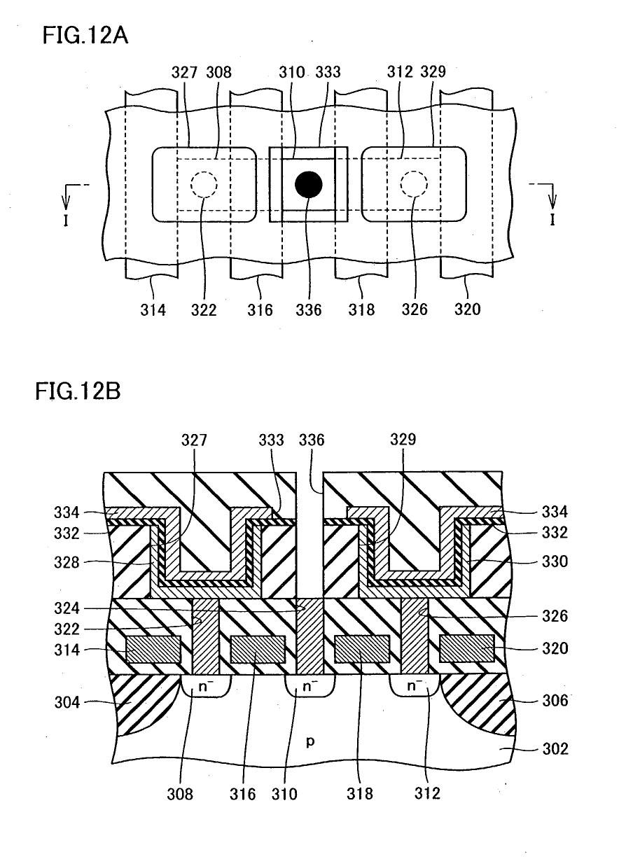

With reference to FIGS. 12A and 12B, an insulation film is again provided on conductive film 334 serving as the capacitor's opposite electrode, or a cell plate, and a bit line contact hole 336 is then provided to provide connection to a conductor in contact hole 324.

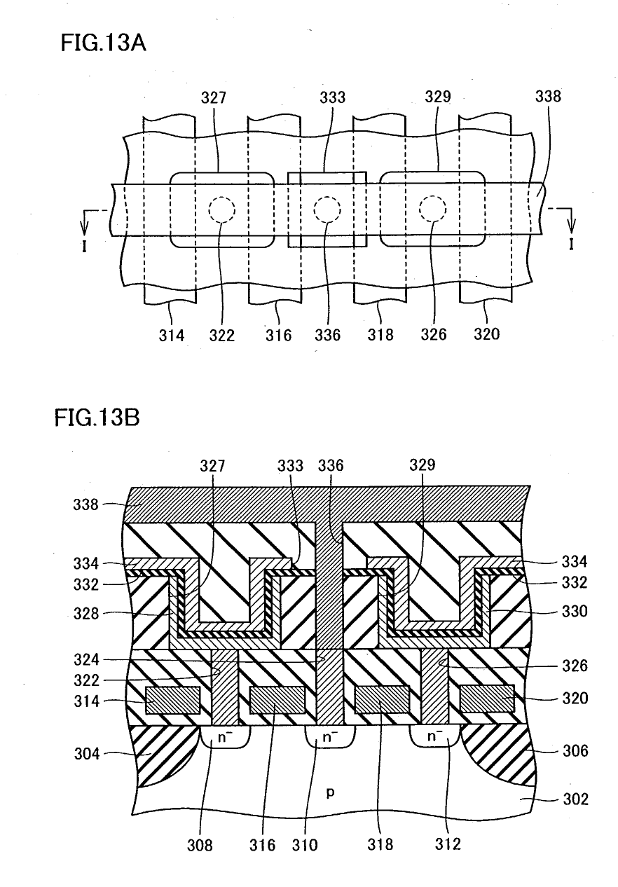

With reference to FIGS. 13A and 13B, bit line contact hole 336 is filled with conductor and a conductive film 338 is then provided. Conductive film 338 is etched away, except for a bit line intersection portion.

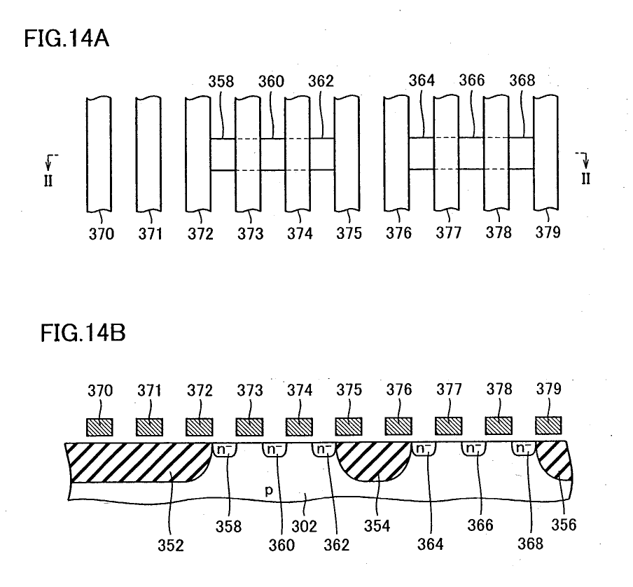

FIGS. 14A-21B illustrate a process for fabricating a ROM cell of memory cell array 24 of FIG. 2.

With reference to FIGS. 14A and 14B, p substrate 302 has a surface provided with device isolation regions 352, 354, 356 and then interconnections 370-379. Of these interconnections, interconnections 371-379 serve as a word line. When n dopant is introduced from above interconnections 370-379 n doped regions 358, 360, 362, 364, 366, 368 are formed in an active region. An n channel MOS transistor having a gate electrode corresponding to interconnection 373, 374, 377, 378 is thus provided.

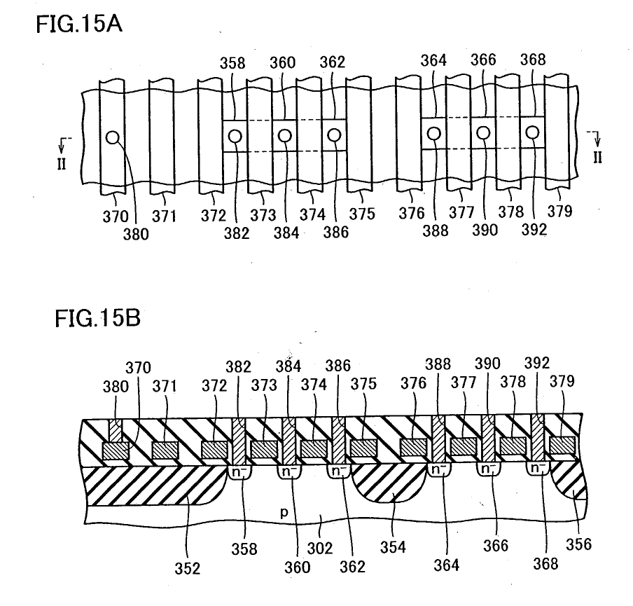

With reference to FIGS. 15A and 15B, an insulation film is provided on a gate interconnection and a memory cell transistor's source/drain contact holes 382, 384, 386, 388, 390, 392 and a contact hole 380 to interconnection 370 set to have a ground potential are then provided.

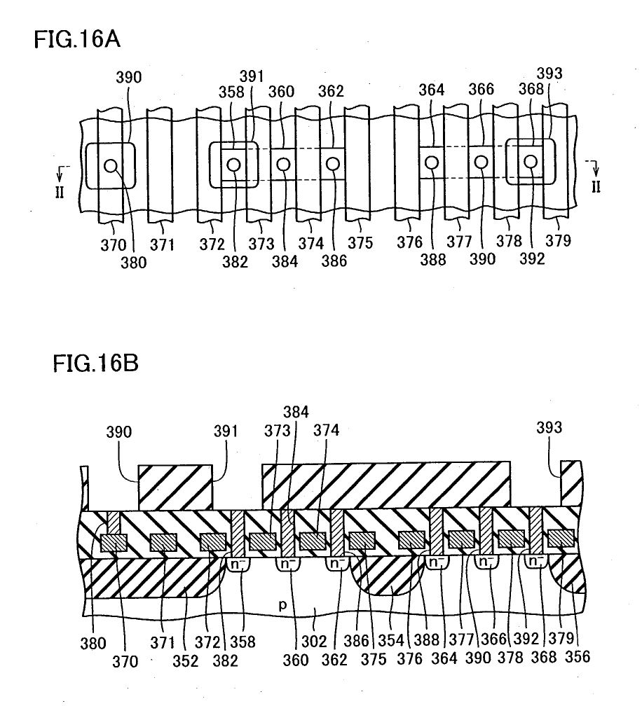

With reference to FIGS. 16A and 16B, an insulation film is again provided, and then in a ROM portion, openings 391, 393 for cell data programming are selectively provided. The selection depends on a polarity of data stored to each memory cell of the ROM portion. More specifically, the programming is effected by preparing a transferring mask corresponding to data, and using the mask to provide an opening.

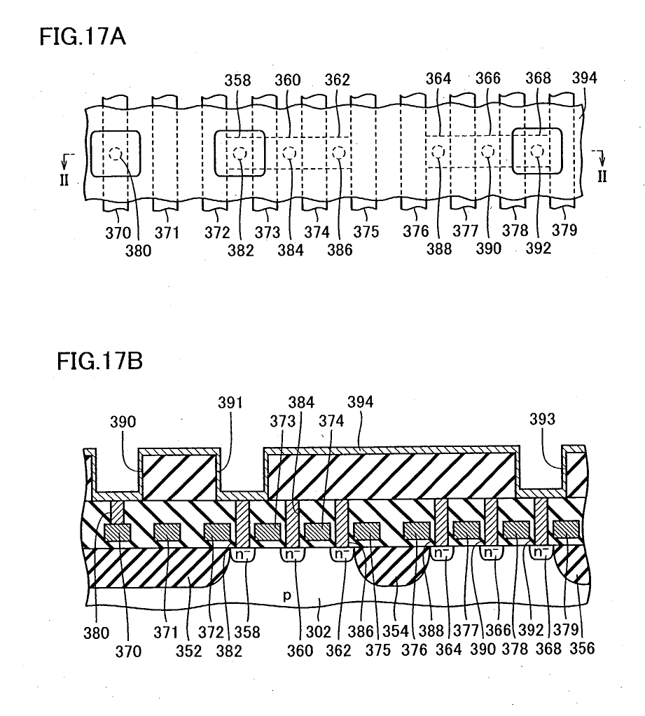

With reference to FIGS. 17A and 17B, the ROM portion is provided with a conductive film 394 serving as an interconnection layer to which a ground potential is applied. Conductive film 394 is provided simultaneously with a storage node at a RAM portion, i.e., conductive film 331 of FIG. 9B.

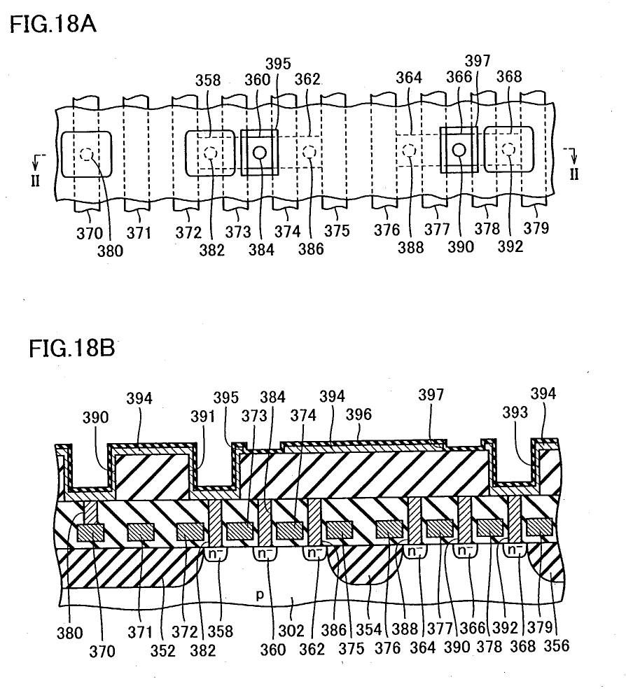

With reference to FIGS. 18A and 18B, resist is applied on an entire surface and exposure is then provided to remove the resist from openings 395, 397. The intermediate product is then etched to remove conductive film 394 from openings 395, 397. In the RAM portion, conductive film 331 remains only in an opening of an insulation film and as a storage node it is divided for each capacitor into conductive films 328, 330. In the ROM portion, by contrast, conductive film 394 excluding openings 395, 397 remains as a single, fixed electrode plate. Conductive film 394 is connected to interconnection 370. Via interconnection 370 a fixed potential is applied to conductive film 394.

Then simultaneously with conductive film 332 between electrodes of the capacitor in the RAM portion shown in FIG. 10B an insulation film 396 is provided.

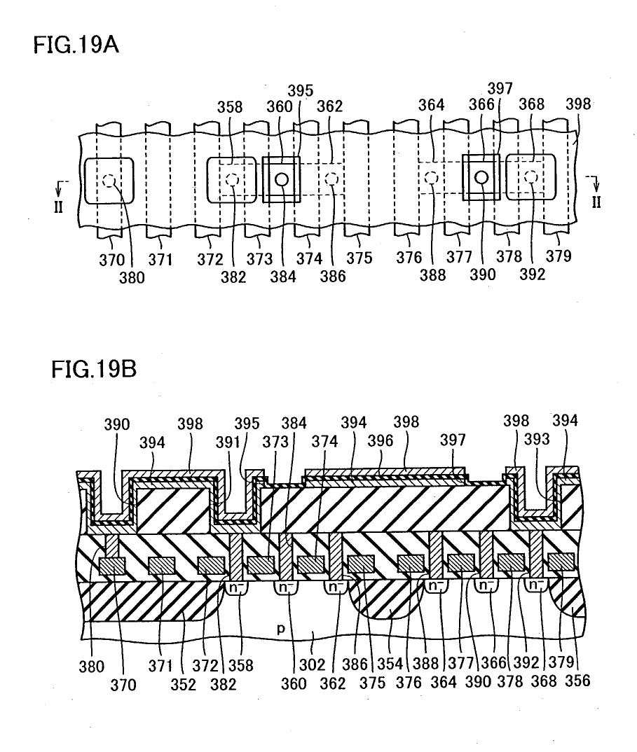

With reference to FIGS. 19A and 19B, on insulation film 396 a conductive film 398 is provided and from opening 395 conductive film 398 is removed to provide a bit line contact hole. For the RAM portion, conductive film 398 corresponds to conductive film 334 serving as a cell plate or a capacitor's opposite electrode.

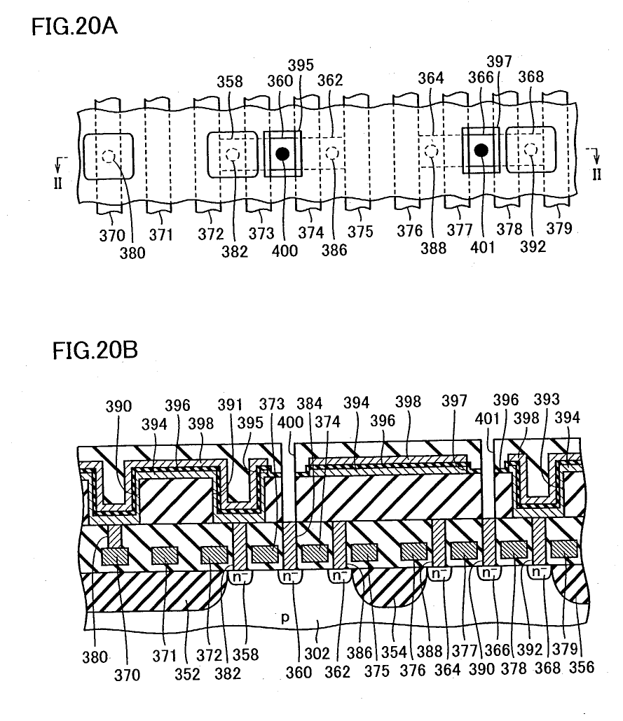

With reference to FIGS. 20A and 20B, an insulation film is provided on conductive film 398 and conduct holes 400, 401 are then provided for bit line.

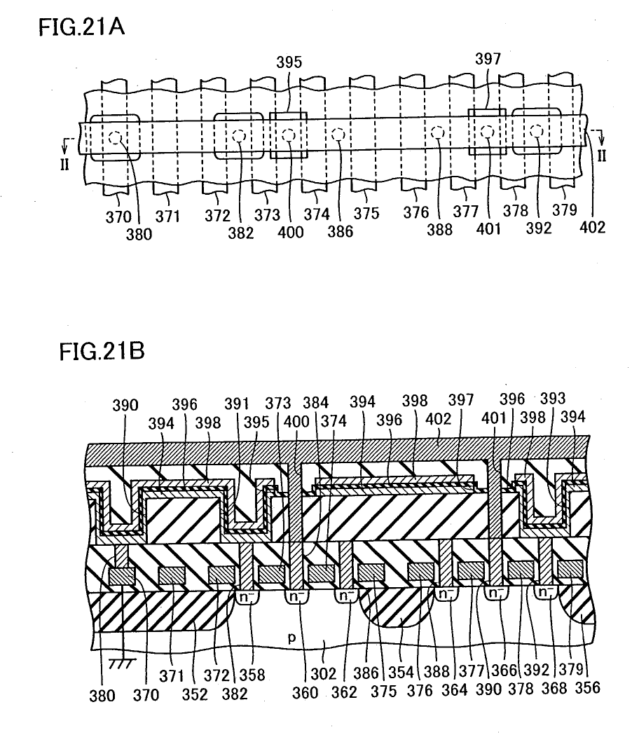

With reference to FIGS. 21A and 21B, contact holes 400, 401 are filled with conductor and an interconnection 402 is then provided as a bit line.

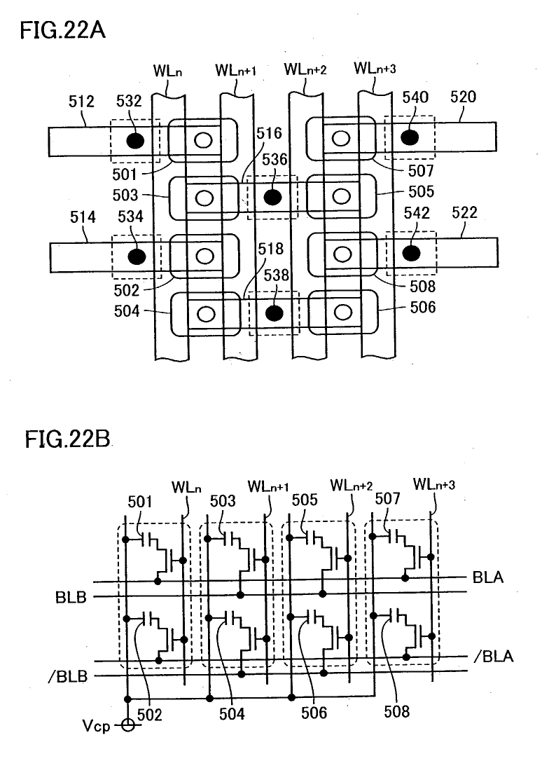

FIGS. 22A and 22B are diagrams for illustrating a storage operation of the RAM portion. FIG. 22A is a schematic plan view. FIG. 22B is an equivalent circuit diagram corresponding to the plan view of FIG. 22A.

With reference to FIGS. 22A and 22B, the RAM portion stores one bit with two capacitors simultaneously connected to complimentary bit line when a single word line is enabled. More specifically, a pair of capacitors 501, 502 are simultaneously selected by a word line WLn and store one bit. A pair of capacitors 503, 504 are simultaneously selected by a word line WLn+1 and store one bit. A pair of capacitors 505, 506 are simultaneously selected by a word line WLn+2 and store one bit. Similarly, a pair of capacitors 507, 508 are simultaneously selected by a word line WLn+3 and store one bit.

Note that in the figure, reference numerals 512, 514, 516, 518, 520, 522 denote an active region and contact hole 532, 534, 540, 542 is a bit line contact hole for connecting a transistor and a corresponding bit line together. Also note that in FIG. 22A no bit line is shown to clearly show capacitors, contact holes and the like. Contact hole 532, 540 is a contact hole for connection to a bit line BLA. A contact hole 536 is a contact hole for connection to a bit line BLB. Contact hole 534, 532 is a contact hole for connection to a bit line /BLA. A contact hole 538 is a contact hole for connection to a bit line /BLB.

Although not shown in the figure, bit lines BLD, /BLD and bit lines BLC, /BLC are connected to a cross coupled sense amplifier receiving a complimentary signal, as has been described with reference to FIG. 3, for operation.

When the sense amplifier is enabled, one bit line attains power supply potential VddL and the other bit line is set to have a ground potential. In the RAM portion, in write operation a storage node of one of capacitors 501, 502 is held by the sense amplifier at the power supply potential and a storage node of the other at the ground potential. For example, as power supply potential VddL a potential of approximately 0.8 to 2.5V is used. Other capacitor pairs also have one capacitor with a storage node held at the power supply potential and the other with a storage node held at the ground potential.

In read operation an electric charge from a memory cell capacitor is read on a bit line pair complimentarily. A variation in potential introduced thereby in the bit line pair is amplified by the sense amplifier to read data.

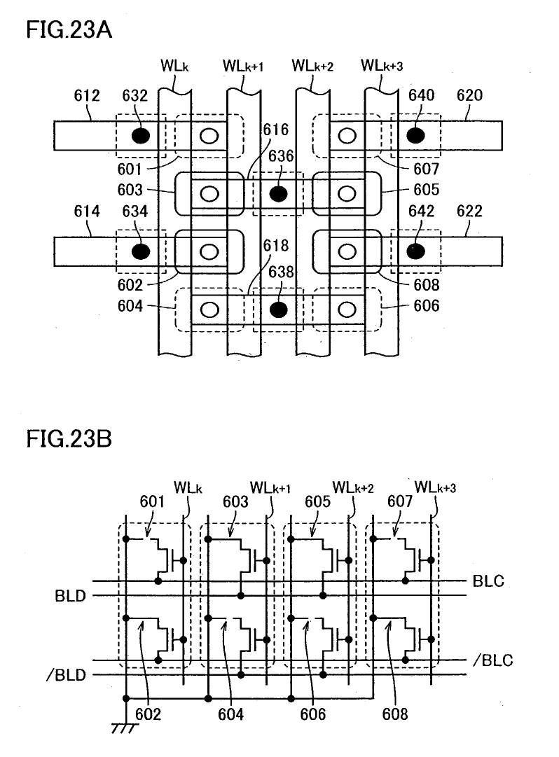

FIGS. 23A and 23B are diagrams for illustrating storing and reading data to and from the ROM portion.

With reference to FIGS. 23A and 23B, an insulation film is provided with openings 601-608 selectively in accordance with data to be stored. As shown in FIG. 23A, openings 601, 604, 606, 607 are indicated by broken line and openings 602, 603, 605, 608 are indicated by solid line. This indicates that, as shown in FIG. 23B, if a transistor having one end connected to a bit line has the other end corresponding to a source/drain region coupled with a ground potential, FIG. 23A employs a solid line to indicate that that an opening is provided, and if the transistor does not have the other end coupled with the ground voltage then the figure employs a broken line to indicate that no opening is provided.

Note that FIG. 23A does not show any bit line to clearly show an active region, a contact hole and the like. Active regions 612, 620 are provided with contact holes 632, 640, respectively, for connection to a bit line, which are contact holes for connection to a bit line BLC. Active region 616 is provided with a bit line contact hole 636, which is a contact hole for connection to a bit line BLD. Similarly, active regions 614, 622 are provided with bit line contact holes 634, 642, respectively, which are contact holes for connection to a bit line /BLC. An active region 618 is provided with a bit line contact hole 638, which is a contact hole for connection to a bit line /BLD.

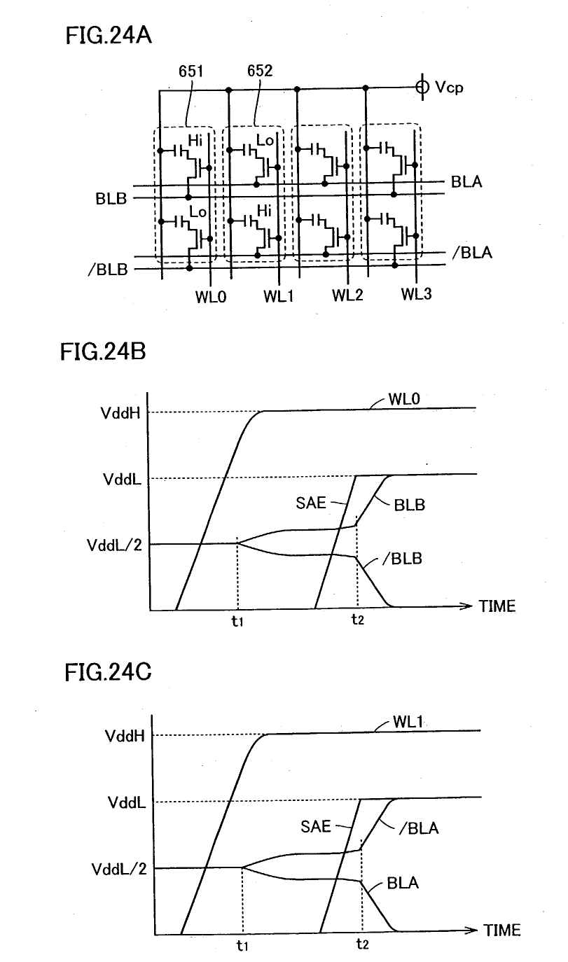

FIGS. 24A-24C are diagrams for illustrating a read operation of the RAM portion.

With reference to FIGS. 24A and 24B, data is read from memory cell unit 651, as described hereinafter. Initially as a word line's voltage a power supply potential VddH higher than an array voltage is used. For example, it is a potential of 2.5V. Furthermore, as a cell plate potential Vcp serving as serving as an opposite electrode of a storage node, ½ of the array voltage, i.e., VddL/2 is applied. Storing data to two memory cell capacitors complimentarily, as described above, is referred to as a twin cell system.

At time T1 word line WL0 is enabled and responsively bit line BLB slightly increases in potential, corresponding to the high level, whereas bit line /BLB slightly drops in potential, corresponding to data Lo. At time T2 sense amplifier enable signal SAE is activated and responsively a bit line's potential difference is amplified and the bit line BLB potential increases to power supply potential VddL and the bit line /BLB potential drops to a ground potential.

With reference to FIGS. 24A and 24C, data is read from memory cell unit 652, as described hereinafter. Initially at time T1 word line WL1 is enabled and responsively bit line BLA slightly drops in potential, corresponding to data Lo. Bit line /BLA slightly increases in potential, corresponding to data Hi.

At time t2 sense amplifier enable signal SAE is enabled and responsively the bit line BLA potential drops to the ground potential and the bit line /BLA potential increases to power supply potential VddL.

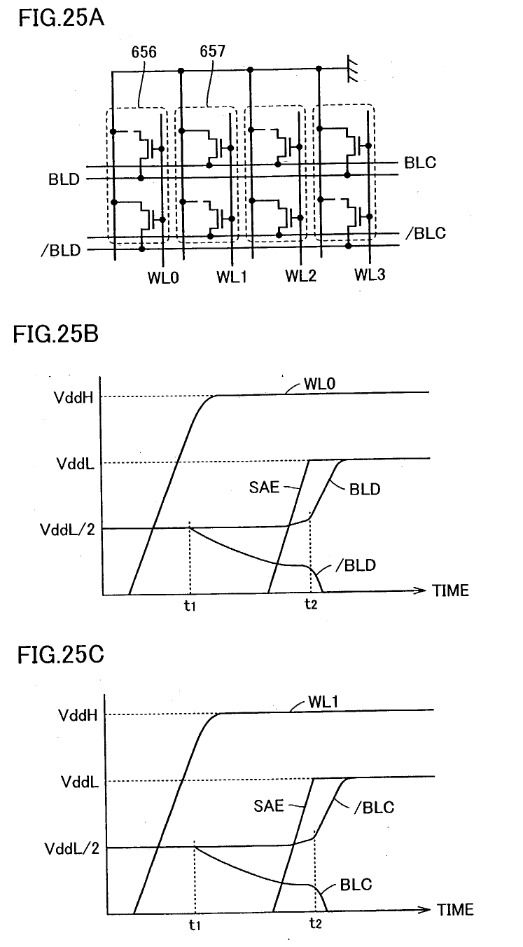

FIGS. 25A-25C are diagrams illustrating a read operation of the ROM portion.

With reference to FIGS. 25A and 25B an operation reading from memory cell unit 656 will be described. At time T1 word line WL0 is enabled and responsively bit line /BLD is connected to a ground potential via an access transistor. Bit line BLD has its potential held at potential VddL/2 since no opening is provided and the bit line is not connected to the ground potential when the access transistor conducts.

At time t2 sense amplifier enable signal SAE is activated, attaining power supply potential VddL, and a potential difference introduced between bit lines BLD and /BLD is expanded. The bit line BLD potential increases to power supply potential VddL and the bit line /BLD potential drops to the ground potential.

With reference to FIGS. 25A and 25C an operation reading from memory cell unit 657 will be described.

At time T1 word line WL1 is enabled and responsively bit line BLC is coupled with a ground potential via an access transistor. Bit line /BLC, with no opening, holds potential VddL/2 even when the access transistor conducts.

At time t2 sense amplifier enable signal SAE is activated and responsively a sense amplifier is enabled to amplify a difference in potential between bit lines BLC and /BLC. Thus the bit line /BLC potential increases to power supply potential VddL and the bit line BLC potential drops to the ground potential.

Thus in the semiconductor device of the first embodiment, as shown in FIG. 2, the RAM portion and the ROM portion use exactly the same sense amplifier circuit and as a result the RAM portion can be altered into the ROM portion by modifying a mask of a storage node electrode of a capacitor of a RAM circuit and programming a mask for an opening of a memory cell capacitor. In other words, a DRAM cell can be altered into ROM by revising a slice mask.

Second Embodiment

The first embodiment has shown that a so-called twin cell DRAM can be altered into a twin cell ROM. In contrast, a single cell DRAM, a single memory cell including a single transistor and capacitor, can also be altered into ROM by previously preparing a DRAM dummy cell region as a common circuit therefor.

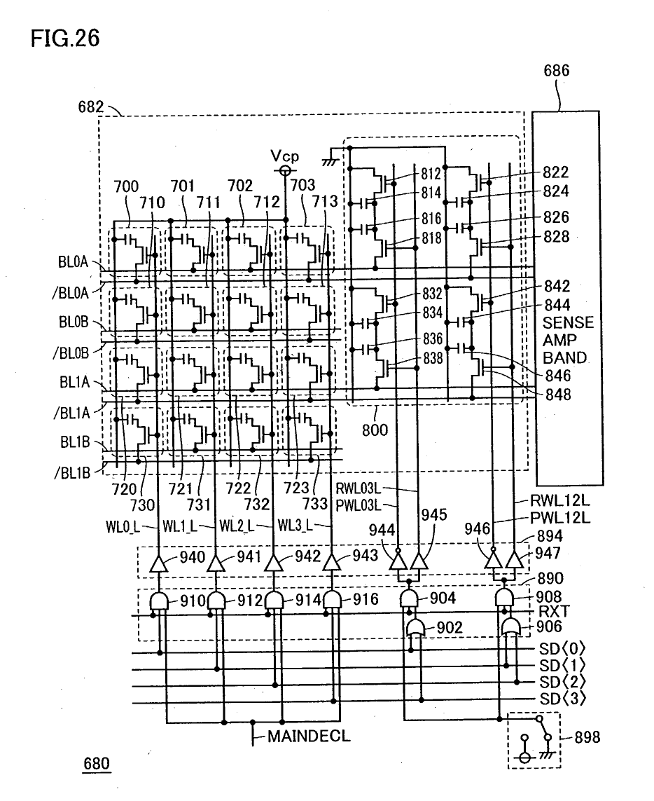

FIG. 26 is a circuit diagram showing a RAM portion of a main portion 680 of the semiconductor memory device of the present invention in a second embodiment. The RAM portion is arranged on a right side of a sense amplifier 686.

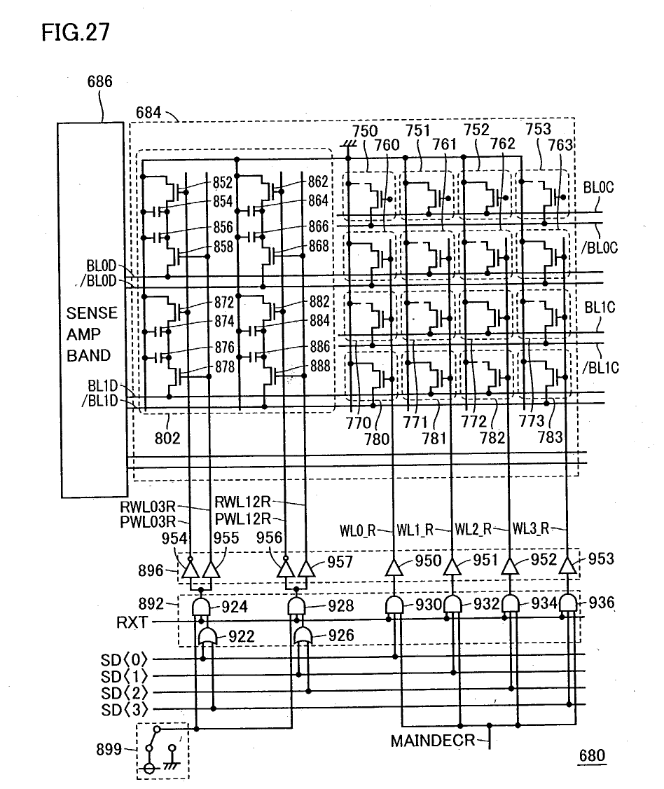

FIG. 27 is a circuit diagram showing a ROM portion of main portion 680 of the semiconductor memory device in a second embodiment. The ROM portion is arranged on a left side of a sense amplifier 686.

With reference to FIGS. 26 and 27, main portion 680 includes a memory cell array 682 operating as DRAM, a memory cell array 684 operating as ROM, a sense amplifier band 686 shared by memory cell arrays 682 and 684, a row decode circuit 890 provided to correspond to memory cell array 682, a word line driver 894 operative in response to an output received from row decode circuit 890 to drive a word line, a row decode circuit 892 provided to correspond to memory cell array 684, and a word line driver 896 operative in response to an output received from row decode circuit 892 to drive a word line.

Main portion 680 also includes switches 898, 899 for switching the control of row decode circuits 890, 892 in accordance with whether to perform the RAM or ROM operation.

Memory cell array 682 includes memory cells 700-733 similar to those of a typical single cell DRAM, and a reference cell 800.

Memory cells 701, 702 are connected to bitline BL0A. Memory cells 700, 703 are connected to bit line /BL0A. Memory cells 711, 712 are connected to bit line BL0B. Memory cells 710, 713 are connected to bit line /BL0B.

Memory cells 721, 722 are connected to bit line BL1A. Memory cells 720, 723 are connected to bit line /BL1A. Memory cells 731, 732 are connected to bit line BL1B. Memory cells 730, 733 are connected to bit line /BL1B.

Memory cells are connected to word lines, as will be described hereinafter. Memory cells 700, 710, 720, 730 are connected to word line WL0_L. Memory cells 701, 711, 721, 731 are connected to word line WL1_L. Memory cells 702, 712, 722, 732 are connected to word line WL2_L. Memory cells 703, 713, 723, 733 are connected to word line WL3_L.

Memory cells 700-733 each include an access transistor and a capacitor connected in series between a bit line connected thereto and a cell plate. The access transistor has its gate connected to a word line connected to a memory cell.

Reference cell 800 includes n channel MOS transistors 818, 812 connected in series between bit line BL0A and a ground node and having their respective gates connected to word lines RWL03L, PWL03L, respectively, and two capacitors 814, 816 connected in parallel between a node connecting n channel MOS transistors 818, 812 together and a ground node.

Reference cell 800 further includes n channel MOS transistors 828, 822 connected in series between bit line /BL0A and a ground node and having their respective gates connected to word lines RWL12L, PWL12L, respectively, and two capacitors 826, 824 connected in parallel between a node connecting n channel MOS transistors 828, 822 together and a ground node.

Reference cell 800 further includes n channel MOS transistors 838, 832 connected in series between bit line BLiA and a ground node and having their respective gates connected to word lines RWL03L, PWL03L, respectively, and two capacitors 836, 834 connected in parallel between a node connecting n channel MOS transistors 838, 832 together and a ground node.

Reference cell 800 further includes n channel MOS transistors 848, 842 connected in series between bit line /BL1A and a ground node and having their respective gates connected to word lines RWL12L, PWL12L, respectively, and two capacitors 846, 844 connected in parallel between a node connecting n channel MOS transistors 848, 842 together and a ground node.

Switch 898 is set to select a ground potential to allow memory cell array 682 to provide a typical DRAM operation. Row decode circuit 890 includes an AND circuit 910 receiving signals RXT, SD<0> and a main decode signal MAINDECL at an input, an AND circuit 912 receiving signals RXT, SD<1> and main decode signal MAINDECL at an input, an AND circuit 914 receiving signals RXT, SD<2> and main decode signal MAINDECL at an input, and an AND circuit 916 receiving signals RXT, SD<3> and main decode signal MAINDECL at an input.

Row decode circuit 890 also includes an OR circuit 902 receiving signals SD<0>, SD<3>, an AND circuit 904 having first and second inputs receiving an output from OR circuit 902 and signal RXT, respectively, and a third input coupled with a ground potential, an OR circuit 906 receiving signals SD<1>, SD<2>, and an AND circuit 908 having first and second inputs receiving an output from OR circuit 906 and signal RXT, respectively, and a third input coupled with a ground potential.

Word line driver 894 includes a buffer circuit 940 operative in response to an output received from AND circuit 910 to drive word line WL0_L, a buffer circuit 941 operative in response to an output received from AND circuit 912 to drive word line WL1_L, a buffer circuit 942 operative in response to an output received from AND circuit 914 to drive a word line WL2_L, and a buffer circuit 943 operative in response to an output received from AND circuit 916 to drive word line WL3_L.

Word line drive 894 also includes an inverter 944 operative in response to an output received from AND circuit 904 to drive word line PWL03L, a buffer circuit 945 operative in response to an output received from AND circuit 904 to drive word line RWL03L, an inverter 946 operative in response to an output received from AND circuit 908 to drive word line PWL12L, and a buffer circuit 947 operative in response to an output received from AND circuit 908 to drive word line RWL12L.

Memory cell array 684 includes memory cells 750-783 each corresponding to a 1-bit storage unit and holding data in non-volatile manner, and a reference cell 802.

Memory cells 751,752 are connected to bit line BL0C. Memory cells 750, 753 are connected to bit line /BL0C. Memory cells 761, 762 are connected to bit line BL0D. Memory cells 760, 763 are connected to bit line /BL0D.

Memory cells 771, 772 are connected to bit line BL1C. Memory cells 770, 778 are connected to bit line /BLIC. Memory cells 781, 782 are connected to bit line BL1D. Memory cells 780, 783 are connected to bit line /BL1D.

Memory cells are connected to word lines, as will be described hereinafter. Memory cells 750, 760, 770, 780 are connected to word line WL0_R. Memory cells 751, 761, 721, 781 are connected to wordline WL1_R. Memory cells 752, 762, 772, 782 are connected to word line WL2_R. Memory cells 753, 763, 773, 783 are connected to word line WL3_R.

Memory cells 750-783 each include an access transistor having one end connected to a corresponding bit line and its gate connected to a corresponding word line. Whether a memory cell's access transistor has the other end coupled with a ground potential depends on data held in the memory cell.

More specifically, memory cells 750, 753, 761, 762, 770, 771, 773, 782 have their access transistors with the other end disconnected from the ground potential or floating. Memory cell 751, 752, 760, 763, 772, 780, 781, 783 have their access transistors with the other end coupled with the ground potential.

Reference cell 802 includes n channel MOS transistors 858, 852 connected in series between bit line BL0D and a ground node and having their respective gates connected to word lines RWL03R, PWL03R, respectively, and two capacitors 854, 856 connected in parallel between a node connecting n channel MOS transistors 858, 852 together and a ground node.

Reference cell 802 further includes n channel MOS transistors 868, 822 connected in series between bit line /BL0D and a ground node and having their respective gates connected to word lines RWL12R, PWL12R, respectively, and two capacitors 866, 864 connected in parallel between a node connecting n channel MOS transistors 868, 862 together and a ground node.

Reference cell 802 further includes n channel MOS transistors 878, 872 connected in series between bit line BL1D and a ground node and having their respective gates connected to word lines RWL03R, PWL03R, respectively, and two capacitors 876, 874 connected in parallel between a node connecting n channel MOS transistors 878, 872 together and a ground node.

Reference cell 802 further includes n channel MOS transistors 888, 882 connected in series between bit line /BLiD and a ground node and having their respective gates connected to word lines RWL12R, PWL12R, respectively, and two capacitors 886, 884 connected in parallel between a node connecting n channel MOS transistors 888, 882 together and a ground node.

Switch 899 is set to select a power supply potential to allow memory cell array 684 to provide ROM operation. Row decode circuit 892 includes an AND circuit 930 receiving signals RXT, SD<0> and a main decode signal MAINDECR at an input, an AND circuit 932 receiving signals RXT, SD<1> and main decode signal MAINDECR at an input, an AND circuit 934 receiving signals RXT, SD<2> and main decode signal MAINDECR at an input, and an AND circuit 936 receiving signals RXT, SD<3> and main decode signal MAINDECR at an input.

Row decode circuit 890 also includes an OR circuit 922 receiving signals SD<0>, SD<3>, an AND circuit 924 having first and second inputs receiving an output from OR circuit 922 and signal RXT, respectively, and a third input coupled with a power supply potential, an OR circuit 926 receiving signals SD<1>, SD<2>, and an AND circuit 928 having first and second inputs receiving an output from OR circuit 926 and signal RXT, respectively, and a third input coupled with a power supply potential.

Word line driver 896 includes a buffer circuit 950 operative in response to an output received from AND circuit 930 to drive word line WL0_R, a buffer circuit 951 operative in response to an output received from AND circuit 932 to drive word line WL1_R, a buffer circuit 952 operative in response to an output received from AND circuit 934 to drive a word line WL2_R, and a buffer circuit 943 operative in response to an output received from AND circuit 936 to drive word line WL3_R.

Word line drive 896 also includes an inverter 954 operative in response to an output received from AND circuit 924 to drive word line PWL03R, a buffer circuit 955 operative in response to an output received from AND circuit 924 to drive word line RWL03R, an inverter 956 operative in response to an output received from AND circuit 928 to drive word line PWL12R, and a buffer circuit 957 operative in response to an output received from AND circuit 928 to drive word line RWL12R.

Sense amplifier band 686 has a configuration similar to that of sense amplifier band 32 described with reference to FIG. 3.

The RAM portion operating as RAM operates, as will be described hereinafter.

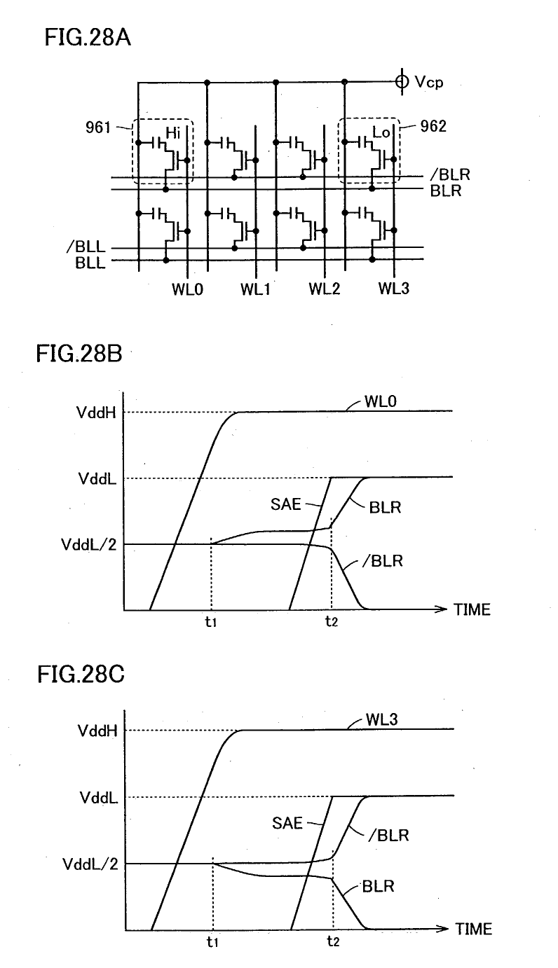

FIGS. 28A-28C are diagrams for illustrating the operation of the RAM portion in the second embodiment.

With reference to FIGS. 28A and 28B, memory cell 961 has its storage node held at potential VddL corresponding to the Hi level for the sake of illustration.

At time t1 electric charge held in the capacitor of memory cell 961 is discharged on bit line BLR in response to word line WL0 being enabled and the bit line BLR potential slightly increases. The bit line BLR potential slightly increases. The bit line /BLR potential maintains potential VddL/2.

At time t2 signal SAE is activated and responsively a sense amplifier operates to amplify a difference in potential between bit lines BLR and /BLR. As a result the bit line BLR potential increases to power supply potential VddL and the bit line /BLR potential drops to the ground potential.

With reference to FIGS. 28A and 28C, the potential of the storage node of memory cell 962 is held at the ground potential corresponding to the Lo level.

At time t1 word line WL3 is enabled and responsively the memory cell 962 storage node having the ground potential receives an electric charge from bit line BLR. The bit line BLR potential slightly drops. The bit line /BLR potential maintains potential VddL/2.

At time t2 signal SAE is activated and responsively a sense amplifier operates to amplify a difference in potential between bit lines BLR and /BLR. In other words, it is bit line /BLR precharged to potential VddL/2 that is compared in the sense amplifier with bit line BLR from which an electric charge flows to a memory cell. Responsively the bit line BLR potential increases to power supply voltage VddL and the bit line BLR potential drops to the ground potential.

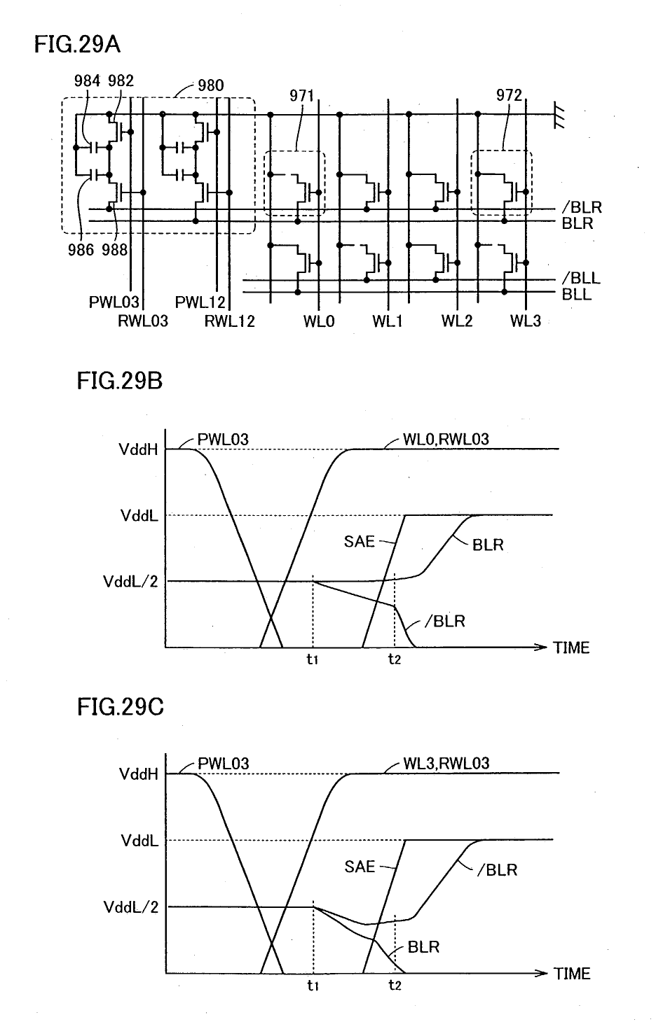

FIGS. 29A-29C are diagrams for illustrating a read operation of the ROM portion of the second embodiment.

With reference to FIGS. 29A and 29B, a memory cell 971 is not provided with an opening corresponding to a memory cell capacitor and a bit line does not have a potential varying when the access transistor conducts. As such, setting a node to be compared to have potential VddL/2, as in the RAM portion, prevents a difference in potential. Accordingly, the potential of the node to be compared by a sense amplifier is set to be a potential intermediate between a ground potential and potential VddL/2. To do so, data corresponding to the ground potential is written to a reference cell 980 before data is read or prior to time t1 during a precharging period. Reference cell 980 is then connected to bit line /BLR paired with bit line BLR having connected thereto memory cell 971 to be read. The potential intermediate between the ground potential and potential VddL/2 is thus generated.

More specifically, prior to time t1 word line PWL03 is set to have power supply potential VddH to provide the capacitors 984, 986 storage node with a ground potential.

At time t1 word line RWL03 attains power supply potential VddH or is enabled and thereby access transistor 988 conducts and an electric charge flows from bit line /BLR precharged to potential VddL/2, to the capacitors 984, 986 storage node. The bit line /BLR potential slightly drops.

By contrast, when at time t1 word line WL0 is enabled the bit line BLR potential nonetheless maintains a precharged potential, potential VddL/2, since the memory cell 971 access transistor has the other end floating, not coupled with a ground node.

At time T2 signal SAE attains power supply potential VddL or activated and responsively a sense amplifier operates to amplify a difference in potential between bit lines BLR and /BLR. As a result, the bit line /BLR potential is set to be a ground potential and the bit line BLR potential is set to be power supply potential VddL.

With reference to FIGS. 29A and 29C a memory cell 971 has its data read, as described hereinafter. Memory cell 972 differs from memory cell 971 in that the former's access transistor has one end connected to bit line BLR and the other end coupled with a ground potential. This corresponds to that for DRAM a memory cell capacitor's opening is provided.

Up to time t1 an operation similar to that described with reference to FIG. 29B is performed.

At time t1 word line RWL03 is enabled and, similarly as has been described with reference to FIG. 29B, the bit line /BLR potential slightly drops. In memory cell 972 the access transistor conducts in response to word line WL3 being enabled and bit line BLR is coupled via the access transistor with a ground node. The bit line BLR potential varies further toward the ground potential than the bit line /BLR potential.

At time t2 signal SAE is activated. Responsively a sense amplifier operates to amplify a difference in potential between bit lines BLR and /BLR. Responsively, the bit line BLR potential is set to be the ground potential and the bit line /BLR potential varies to attain power supply potential VddL.

Note that as shown in FIG. 29A, for a reference cell two typical memory cell capacitors connected in parallel can be used. When word lines WL0, WL3 are enabled, two types of dummy word lines PWL03, RWL03 are operated, and when word lines WL1, WL2 are enabled, dummy word lines PWL12, RWL12 are operated.

Third Embodiment

In a third embodiment will be described an exemplary application provided when a RAM portion substitutable to be a ROM portion by changing a slice mask, such as has been described in the first and second embodiments, is applied to a microcomputer.

When a program is initially developed, a microcomputer with a flash memory is typically used in an electronic circuit. In mass-production or after a program code has been fixed a ROM-incorporated microcomputer is used.

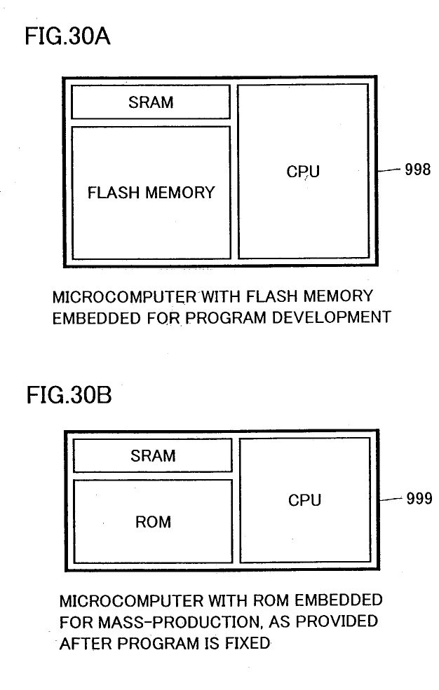

FIGS. 30A and 30B are diagrams for illustrating a microcomputer for program development and that after a program has been fixed, respectively.

With reference to FIG. 30A, the microcomputer for program development includes a flash memory capable of electrically rewriting non-volatile data, a static random access memory (SRAM) serving as a working memory such as a main storage memory, and a central processing unit (CPU). Having the flash memory store the CPU's program code allows a program developer to rapidly improve a program while confirming the effect of the improvement.

By contrast, a microcomputer 999 used after the program has been fixed includes a non-rewritable ROM, a SRAM, and a CPU. The ROM has a small area relative to the flash memory, which allows mass-production at reduced cost.

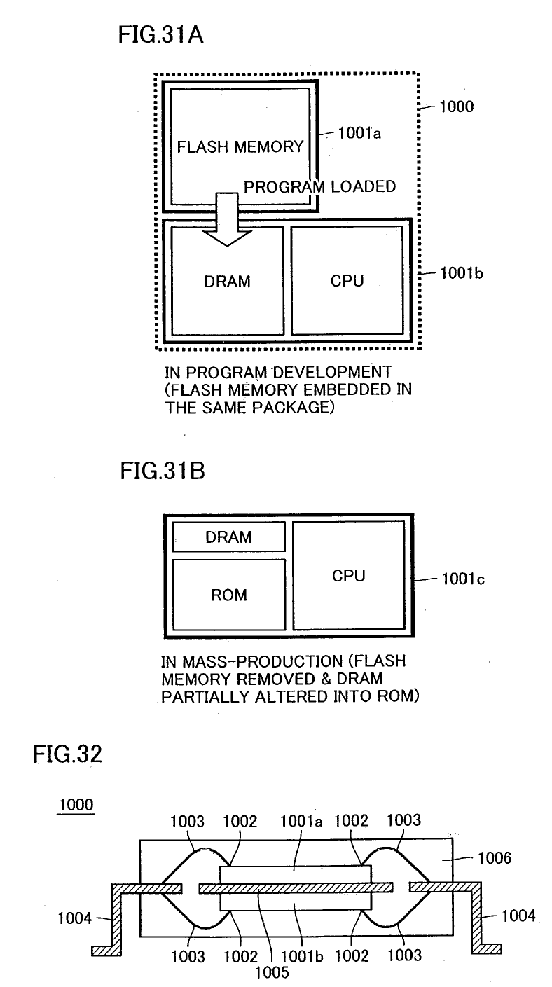

FIGS. 31A and 31B are diagrams for illustrating a development using a microcomputer incorporating the semiconductor memory device of the present invention.

With reference to FIG. 31A, a microcomputer for development 1000 includes a microcomputer chip 1001b and a flash memory chip 1001a accommodated in the same package and externally attached. Microcomputer chip 1001b includes a CPU and a DRAM having a memory region entirely corresponding to RAM. In development, a program is loaded from external flash memory chip 1001a to the DRAM and the CPU is operated.

With reference to FIG. 31B, in mass-production a slice mask can be changed to alter into ROM a portion corresponding to a RAM of a program region of the chip for development. A microcomputer chip for mass-production 1001c includes a DRAM, a ROM portion corresponding to a portion which is originally a DRAM and has been altered, and a CPU. Microcomputer chip 1001c until a transistor completes is fabricated in a process using the same mask as the FIG. 31A microcomputer chip 1001b. As such, they are of the same size. Flash memory chip 1001a is dispensed with, which can provide a reduced development cost. Furthermore, a master slice of microcomputer chip 1001b having undergone the transistor fabrication process and held can exactly be used for producing microcomputer chip 1001c so that mass-produced chips can rapidly be supplied to users.

FIG. 32 shows one example of a configuration accommodating in a package the microcomputer for development described in FIG. 31A.

With reference to FIG. 32, flash memory chip 1001a is arranged on an upper surface of a die pad 1005. Microcomputer chip 1001b is arranged on a lower surface of die pad 1005. Chip 1001a has an input/output pad 1002 connected by a bonding wire 1003 to a lead 1004. For example, for a pad receiving an address signal, from lead 1004 to both pad 1002 of chip 1001a and pad 1002 of chip 1001b connection is made. For other pads, a required chip is connected to lead 1004, as required.

This can eliminate the necessity of developing a flash embedding process required, as shown in FIG. 30A, and developing two types of computers, a flash version and a ROM version. In a conventional system when RAM and ROM regions have different memory capacity ratio an additional LSI chip still needs to be developed, whereas in the present system a single master slice can also advantageously be used for two LSIs having different capacity ratio.

The DRAM portion of FIG. 31B bears the responsibility of the conventional SRAM portion shown in FIG. 30B. The DRAM that configures a portion having conventionally employing a SRAM allows the same storage capacity in a reduced size. The FIG. 31B DRAM and ROM's capacity ratio is determined by the application of the type of product of interest.

As has been described in the embodiments, in a development stage, memory incorporated in a semiconductor memory device is entirely produced to be RAM, and in a mass-production stage, a region accommodating a program is altered into ROM by changing a mask after an interconnection process. In altering into the ROM, an electrode plate having been a storage node of a capacitor of a DRAM is connected for each memory cell array and coupled with a fixed potential. Whether to couple an access transistor with a fixed potential depends on whether provide an opening of an insulation film forming a capacitor of the DRAM at an internal wall.

As such, a chip for development and that for mass-production can commonly be fabricated up to an intermediate step of the process and the chip for mass-production can rapidly be supplied. As such, a semiconductor device can be provided to provide for transition from a program development stage to a mass-production stage at low cost.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a first memory cell array arranged in a first region to store information in a volatile manner, said first memory cell array including a first electrode plate receiving a first fixed potential, a plurality of second electrode plates arranged opposite to said first electrode plate with an insulation film placed therebetween, a plurality of first bit lines, a plurality of first word lines and a plurality of first access transistors each having one end connected to a respective one of said plurality of second electrode plates, said plurality of first access transistors each having the other end connected to a corresponding one of said plurality of first bit lines, and a control electrode connected to a corresponding one of said plurality of first word lines; and
a second memory cell array arranged in a second region to store information in a non-volatile manner, said second memory cell array including a third electrode plate receiving a second fixed potential, said third electrode plate and said plurality of second electrode plates being fabricated in a single process, said second memory cell array further including a plurality of second bit lines, a plurality of second word lines and a plurality of second access transistors, said plurality of second transistors each having a control electrode connected to a corresponding one of said plurality of second word lines, and one end connected to a corresponding one of said plurality of second bit lines, and the other end of each of said plurality of second access transistors being determined, according to storage information of said second memory cell array, whether or not to be connected to said third electrode plate.

2. The semiconductor memory device according to claim 1, further comprising a semiconductor substrate provided with said plurality of first and second transistors, wherein said first electrode plate and said plurality of second electrode plates are stacked on said first access transistor with an interlayer insulating film placed therebetween.

3. The semiconductor device according to claim 1, further comprising a sense amplifier band shared by said first and second memory cell arrays.

4. The semiconductor device according to claim 3, wherein said sense amplifier band includes a plurality of sense amplifier circuits each responsive to an address signal to be in connection to either of one of said plurality of first bit lines and one of said plurality of second bit lines selectively.

5. The semiconductor device according to claim 1, wherein:
said plurality of first access transistors have complimentarily paired two thereof simultaneously conduct for reading one bit of information;
said plurality of second transistors have complimentarily paired two thereof simultaneously conduct for reading one bit of information.

6. The semiconductor device according to claim 5, wherein:
complimentarily paired two of said plurality of first access transistors are connected respectively to complimentarily paired two of said plurality of first bit lines; and
complimentarily paired two of said plurality of second access transistors are connected respectively to complimentarily paired two of said plurality of second bit lines.

7. The semiconductor device according to claim 1, wherein:
one of said plurality of first access transistors selectively conducts for reading one bit of information; and
one of said plurality of second transistors selectively conducts for reading one bit of information.

8. The semiconductor device according to claim 7, further comprising:
a reference memory cell selected when said plurality of second access transistors are selected; and
a sense amplifier circuit connected to a predetermined one of said plurality of second bit lines with a selected one of said plurality of second transistors connected thereto, and said reference memory cell.

9. The semiconductor device according to claim 1, further comprising a central processing unit (CPU) receiving data from said first and second memory cell arrays.
